(19) United States
(12) Patent Application Publication
(10) Pub. No.: US 2024/0272543 A1
(43) Pub. Date: Aug. 15, 2024

(54) DETERMINING ROUNDED CONTOURS FOR LITHOGRAPHY RELATED PATTERNS

(71) Applicant: ASML NETHERLANDS B.V., Veldhoven (NL)

(72) Inventors: Wen LYU, San Jose, CA (US); Mir Farrokh SHAYEGAN SALEK, Stamford, CT (US); Xiaobo XIE, Milpitas, CA (US); Jen-Shiang WANG, Sunnyvale, CA (US)

(73) Assignee: ASML NETHERLANDS B.V., Veldhoven (NL)

(21) Appl. No.: 18/565,889

(22) PCT Filed: May 27, 2022
(86) PCT No.: PCT/EP2022/064430

§ 371 Date: Nov. 30, 2023

Related U.S. Application Data
(60) Provisional application No. 63/197,893, filed on Jun. 7, 2021.

(51) Int. Cl. G03F 1/36; G03F 7/00

(52) U.S. Cl. CPC G03F 1/36; G03F 7/70441; G03F 7/705

(57) ABSTRACT

A methods and systems for determining rounded contours of target contours or other lithography related contour for mask design. The method includes converting a contour representation to (i) a first set of contour point locations in a first dimension (e.g., x) and (ii) a second set of contour point locations in a second dimension (e.g., y). A signal function is determined based on the first and second sets of contour point locations, the signal function indicative of different segments of the contour representation. The first set of contour point locations is updated based on a first filter function and the signal function, and the second set of contour point locations is updated based on a second filter function and the signal function. Based on the updated contour point locations, a rounded contour of the contour representation is generated.

### CROSS-REFERENCE TO RELATED APPLICATIONS

This application claims priority of U.S. application 63/197,893 which was filed on 7 Jun. 2021, and which is incorporated herein in its entirety by reference.

### TECHNICAL FIELD

The description herein relates to a method or a system to determine rounded contours for any patterns related to lithography including mask patterns to be employed in semiconductor manufacturing.

### BACKGROUND

A lithographic projection apparatus can be used, for example, in the manufacture of integrated circuits (ICs). In such a case, a patterning device (e.g., a mask) may contain or provide a circuit pattern corresponding to an individual layer of the IC (“design layout”), and this circuit pattern can be transferred onto a target portion (e.g. comprising one or more dies) on a substrate (e.g., silicon wafer) that has been coated with a layer of radiation-sensitive material (“resist”), by methods such as irradiating the target portion through the circuit pattern on the patterning device. In general, a single substrate contains a plurality of adjacent target portions to which the circuit pattern is transferred successively by the lithographic projection apparatus, one target portion at a time. In one type of lithographic projection apparatuses, the circuit pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the circuit pattern on the patterning device are transferred to one target portion progressively. Since, in general, the lithographic projection apparatus will have a magnification factor M (generally <1), the speed F at which the substrate is moved will be a factor M times that at which the projection beam scans the patterning device. More information with regard to lithographic devices as described herein can be gleaned, for example, from U.S. Pat. No. 6,046,792, incorporated herein by reference.

Prior to transferring the circuit pattern from the patterning device to the substrate, the substrate may undergo various procedures, such as priming, resist coating and a soft bake. After exposure, the substrate may be subjected to other procedures, such as a post-exposure bake (PEB), development, a hard bake and measurement/inspection of the transferred circuit pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

As noted, lithography is a central step in the manufacturing of ICs, where patterns formed on substrates define functional elements of the ICs, such as microprocessors, memory chips etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e., less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a circuit designer in order to achieve particular electrical functionality and performance. To overcome these difficulties, sophisticated fine-tuning steps are applied to the lithographic projection apparatus and/or design layout. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### BRIEF SUMMARY

According to an embodiment of the present disclosure, there is provided a method for generating rounded contours for lithographic mask patterns. The method includes converting a contour representation of a mask pattern to 1D representations such as a first set of contour point locations in a first dimension and a second set of contour point locations in a second dimension different from the first dimension. A signal function is determined based on the first set and the second set of contour point locations, the signal function indicative of different segments (e.g., edge, corners, etc.) of the contour representation. The first set of contour point locations is updated based on the first filter function and the signal function, and the second set of contour point locations is updated based on the second filter function and the signal function. Based on the updated first set of contour point locations and the updated second set of contour point locations, a rounded contour of the contour representation of the mask pattern is generated.

In an embodiment, the updating involves generating (i) a first set of weights corresponding to the first set of contour point locations by applying a first filter function to the signal function, and (ii) a second set of weights corresponding to the second set of contour point locations by applying a second filter to the signal function; and updating (i) the first set of contour point locations based on the first filter function and the first set of weights, and (ii) the second set of contour point locations based on the second filter function and the second set of weights.

According to an embodiment, there is provided another method for determining rounded contours for lithographic masks. The method involves converting a contour representation of a mask pattern to a one dimensional (1D) representation using a unit directional vector and constraining the ID representation to satisfy a constrain that is proportional to the unit directional vector. Further, a first function of the 1D representation is determined by taking a gradient of the 1D representation with respect to a first dimension; and a second function of the 1D representation is determined by taking another gradient of the 1D representation with respect to a second dimension, the first and the second functions satisfying the constrain. A first filtered function is generated by applying a first filter to the first function. A second filtered function is generated by applying a second filter to the second function. By combining the first filtered function and the second filtered function of the contour representation, a rounded contour for the mask pattern is generated.

In an embodiment, the method further includes distinguishing a first type of corners (e.g., an inner corner) in the contour representation and a second type of corners (e.g., an outer corner) in the contour representation; and defining the first filter function and/or the second filter function to comprise a filter function for the first type of corners and another filter function for the second type of corners. As an example, the distinguishing of the corners may be achieved by computing a signum function of the first function and the second function of the 1D representation, where a positive value of the signum function indicates the first type of corner, and a negative value of the signum function indicates the second type of corner. As another example, the distinguishing of the corners may be achieved based on a sine of the unit vector along the contour representation.

According to an embodiment, there is provided a non-transitory computer-readable medium for determining mask rule check violations associated with mask features, the medium comprising instructions stored therein that, when executed by one or more processors, cause operations including steps of the method herein.

### BRIEF DESCRIPTION OF THE DRAWINGS

FIG. 1 is a block diagram of various subsystems of a lithography system, according to an embodiment of the present disclosure.

FIG. 2 is a block diagram of simulation models corresponding to the subsystems in FIG. 1, according to an embodiment of the present disclosure.

FIG. 3 is a flow chart of a method of generating rounded contours, according to an embodiment of the present disclosure.

FIG. 4A illustrates an exemplary contour representation of a contour to be printed on a substrate, according to an embodiment of the present disclosure.

FIG. 4B illustrates an exemplary conversion of the contour representation into a set of contour point locations, according to an embodiment of the present disclosure.

FIG. 4C illustrates a rounded contour of the contour FIG. 4A, according to an embodiment of the present disclosure.

FIG. 5A illustrates an exemplary contour represented as a polygon shape in 2D, according to an embodiment of the present disclosure.

FIG. 5B illustrates 1D representations of the contour representation 500, according to an embodiment of the present disclosure.

FIG. 5C illustrates a signal generated using the 1D representations of FIG. 5B, according to an embodiment of the present disclosure.

FIG. 5D illustrates examples of weights for the 1D representations of FIG. 5C, according to an embodiment of the present disclosure.

FIG. 5E illustrates the updated 1D representations of the ID representation of FIG. 5B, according to an embodiment of the present disclosure.

FIG. 5F illustrates an exemplary rounded contour generated from the updated 1D representations of FIG. 5E, according to an embodiment of the present disclosure.

FIG. 6 illustrates different rounded contours generated when same or different filters are applied to the 1D representations, according to an embodiment of the present disclosure.

FIG. 7 is a flow chart of another method for generating rounded contours of a pattern, according to an embodiment of the present disclosure.

FIG. 8A illustrates an exemplary contour representation, according to an embodiment of the present disclosure.

FIG. 8B illustrates the 1D representation upon unfolding the contour of FIG. 8A into a single dimension, according to an embodiment of the present disclosure.

FIG. 8C illustrates and exemplary components of the 1D representation of FIG. 8B, according to an embodiment of the present disclosure.

FIG. 8D illustrates filtered 1D functions of the 1D representation of FIG. 8B generated using a filter FLT1, according to an embodiment of the present disclosure.

FIG. 8E illustrates a rounded contour generated from the filtered 1D functions of FIG. 8D, according to an embodiment.

FIG. 9 illustrates rounded contours obtained according to the present disclosure are not affect by rotation of the contours, according to an embodiment of the present disclosure.

FIG. 10 is a flow diagram illustrating aspects of an example methodology of joint optimization/co-optimization, according to an embodiment of the present disclosure.

FIG. 11 shows an embodiment of a further optimization method, according to an embodiment of the present disclosure.

FIG. 12A, FIG. 12B and FIG. 13 show example flowcharts of various optimization processes, according to an embodiment of the present disclosure.

FIG. 14 is a block diagram of an example computer system, according to an embodiment of the present disclosure.

FIG. 15 is a schematic diagram of a lithographic projection apparatus, according to an embodiment of the present disclosure.

FIG. 16 is a schematic diagram of another lithographic projection apparatus, according to an embodiment of the present disclosure.

FIG. 17 is a more detailed view of the apparatus in FIG. 16, according to an embodiment of the present disclosure.

FIG. 18 is a more detailed view of the source collector module SO of the apparatus of FIG. 16 and FIG. 17, according to an embodiment of the present disclosure.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

The term “optimizing” and “optimization” as used herein refers to or means adjusting a lithographic projection apparatus, a lithographic process, etc. such that results and/or processes of lithography have more desirable characteristics, such as higher accuracy of projection of a design layout on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Further, the lithographic projection apparatus may be of a type having two or more tables (e.g., two or more substrate table, a substrate table and a measurement table, two or more patterning device tables, etc.). In such “multiple stage” devices a plurality of the multiple tables may be used in parallel, or preparatory steps may be carried out on one or more tables while one or more other tables are being used for exposures. Twin stage lithographic projection apparatuses are described, for example, in U.S. Pat. No. 5,969,441, incorporated herein by reference.

The patterning device referred to above comprises, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between circuit devices (such as gates, capacitors, etc.) or interconnect lines, so as to ensure that the circuit devices or lines do not interact with one another in an undesirable way. One or more of the design rule limitations may be referred to as “critical dimensions” (CD). A critical dimension of a circuit can be defined as the smallest width of a line or hole or the smallest space between two lines or two holes. Thus, the CD determines the overall size and density of the designed circuit. Of course, one of the goals in integrated circuit fabrication is to faithfully reproduce the original circuit design on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. More information on such mirror arrays can be gleaned, for example, from U.S. Pat. Nos. 5,296,891 and 5,523,193, which are incorporated herein by reference.
a programmable LCD array. An example of such a construction is given in U.S. Pat. No. 5,229,872, which is incorporated herein by reference.

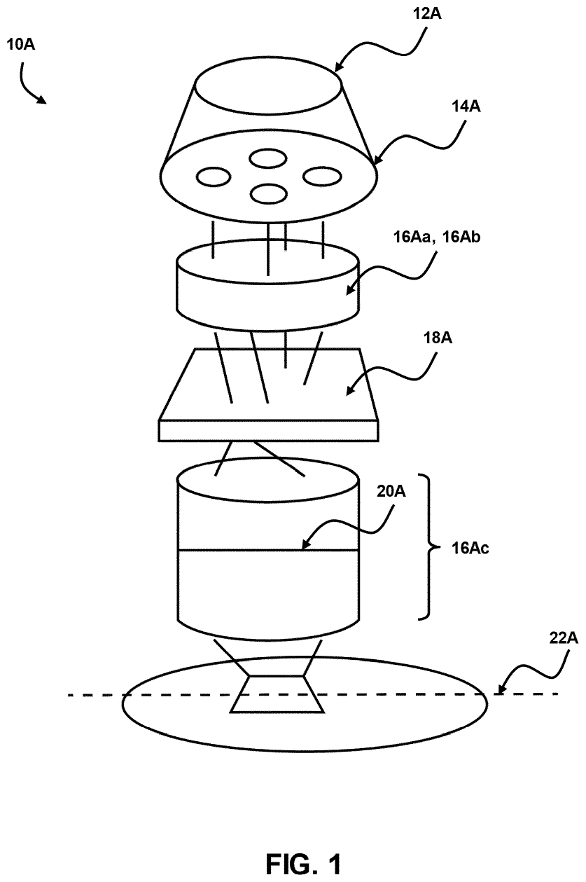

As a brief introduction, FIG. 1 illustrates an exemplary lithographic projection apparatus 10A. Major components are a radiation source 12A, which may be a deep-ultraviolet excimer laser source or other type of source including an extreme ultra violet (EUV) source (as discussed above, the lithographic projection apparatus itself need not have the radiation source), illumination optics which define the partial coherence (denoted as sigma) and which may include optics 14A, 16Aa and 16Ab that shape radiation from the source 12A; a patterning device 14A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θₘₐₓ), n is the Index of Refraction of the media between the last element of projection optics and the substrate, and Θₘₐₓ is the largest angle of the beam exiting from the projection optics that can still impinge on the substrate plane 22A. The radiation from the radiation source 12A may not necessarily be at a single wavelength. Instead, the radiation may be at a range of different wavelengths. The range of different wavelengths may be characterized by a quantity called “imaging bandwidth,” “source bandwidth” or simply “bandwidth,” which are used interchangeably herein. A small bandwidth may reduce the chromatic aberration and associated focus errors of the downstream components, including the optics (e.g., optics 14A, 16Aa and 16Ab) in the source, the patterning device and the projection optics. However, that does not necessarily lead to a rule that the bandwidth should never be enlarged.

In an optimization process of a system, a figure of merit of the system can be represented as a cost function. The optimization process boils down to a process of finding a set of parameters (design variables) of the system that optimizes (e.g., minimizes or maximizes) the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics; the cost function can also be the maximum of these deviations (i.e., worst deviation). The term “evaluation points” herein should be interpreted broadly to include any characteristics of the system. The design variables of the system can be confined to finite ranges and/or be interdependent due to practicalities of implementations of the system. In the case of a lithographic projection apparatus, the constraints are often associated with physical properties and characteristics of the hardware such as tunable ranges, and/or patterning device manufacturability design rules, and the evaluation points can include physical points on a resist image on a substrate, as well as non-physical characteristics such as dose and focus.

In a lithographic projection apparatus, a source provides illumination (i.e., radiation) to a patterning device and projection optics direct and shape the illumination, via the patterning device, onto a substrate. The term “projection optics” is broadly defined here to include any optical component that may alter the wavefront of the radiation beam. For example, projection optics may include at least some of the components 14A, 16Aa, 16Ab and 16Ac. An aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in U.S. Patent Application Publication No. US 2009-0157360, the disclosure of which is hereby incorporated by reference in its entirety. The resist model is related only to properties of the resist layer (e.g., effects of chemical processes which occur during exposure, PEB and development). Optical properties of the lithographic projection apparatus (e.g., properties of the source, the patterning device and the projection optics) dictate the aerial image. Since the patterning device used in the lithographic projection apparatus can be changed, it is desirable to separate the optical properties of the patterning device from the optical properties of the rest of the lithographic projection apparatus including at least the source and the projection optics.

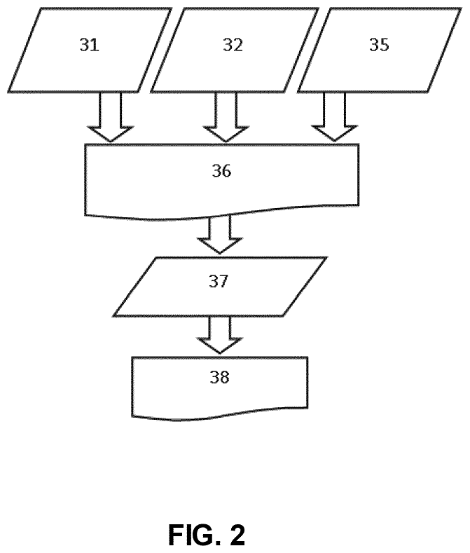

An exemplary flow chart for simulating lithography in a lithographic projection apparatus is illustrated in FIG. 2. A source model 31 represents optical characteristics (including radiation intensity distribution, bandwidth and/or phase distribution) of the source. A projection optics model 32 represents optical characteristics (including changes to the radiation intensity distribution and/or the phase distribution caused by the projection optics) of the projection optics. A design layout model 35 represents optical characteristics (including changes to the radiation intensity distribution and/or the phase distribution caused by a given design layout 33) of a design layout, which is the representation of an arrangement of features on or formed by a patterning device. An aerial image 36 can be simulated from the design layout model 35, the projection optics model 32 and the design layout model 35. A resist image 38 can be simulated from the aerial image 36 using a resist model 37. Simulation of lithography can, for example, predict contours and CDs in the resist image.

More specifically, it is noted that the source model 31 can represent the optical characteristics of the source that include, but not limited to, numerical aperture settings, illumination sigma (o) settings as well as any particular illumination shape (e.g., off-axis radiation sources such as annular, quadrupole, dipole, etc.). The projection optics model 32 can represent the optical characteristics of the projection optics, including aberration, distortion, one or more refractive indexes, one or more physical sizes, one or more physical dimensions, etc. The design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or another file format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (e.g., circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas.

In an embodiment, the design layout or portions of the design layout are used for designing a mask to be employed in the semiconductor manufacturing. A mask design includes determining mask features based on mask optimization simulations and checking whether mask rule checks (MRC) are satisfied. In an embodiment, the mask design includes Manhattan shaped mask feature or curvilinear mask features. The mask features are desired to satisfy mask rule checks associated with mask manufacturing process. As the mask design technology e.g., optical proximity correction (OPC) technology is migrating from Manhattan to curvilinear shapes, current MRC engine can no longer consistently flag MRC violations and drive optimization. In an embodiment, the MRC includes one or more constrains related to geometric properties associated with the mask feature that can be manufactured. For example, the geometric properties include, but not limited, to a minimum CD of a mask feature, a minimum curvature of mask feature that can be manufactured, or a minimum space between two features that can be manufactured.

In semiconductor chips or integrated circuits manufacturing, a mask pattern is usually designed or optimized by computational lithography software (e.g., involving optical proximity correction), so that desired patterns can be printed on a substrate via lithography. However, due to the limitation of mask manufacturing apparatus, a real manufactured mask is different from the designed one. For example, a designed mask may include sharp corners, while, in a manufactured mask, the corner areas may be rounded. This mask pattern difference is substantially amplified at the substrate due to the highly non-linear nature of lithography imaging. Thus, differences caused by mask making should be taken into account in mask modeling and design.

As an example, the designed mask may include 90-degree sharp corners, while the real manufactured one is smooth or has rounded corners. These differences are often called “rounding effect” in a mask manufacturing process. To model the “rounding effect” caused by the mask manufacturing process or any other sources, existing methods round the corner of the designed mask patterns using a certain curvature according to certain rules. This rule determines how large of a curvature be applied for each corner. These methods usually work well on patterns with long segment. However, with continuous shrinkage of the semiconductor node to features of single digit nanometer scale, the mask patterns become more complicated and contain small jogs and staircases, which usually require more complicated rule to compensate for the rounding effects. One issue is the mask pattern after rounding is not continuous with respect to small changes in an input mask pattern resulting in model errors.

The present disclosure provides mechanisms for rounding contours. Advantages of the present method include, but not limited to, that a continuous mask pattern is obtained with respect to small change of input pattern. The methods herein support anamorphic case (e.g., distorted patterns) by applying the same or different filters on x/y coordinate. The methods herein also support cases that have different rounding behavior at inner corners and outer corners. Filters, in the methods herein, can be calibrated based on real mask contours such as measured using scanning electron microscope (SEM) or optical inspection instrument. The contours are smoothed throughout and not limited to corners.

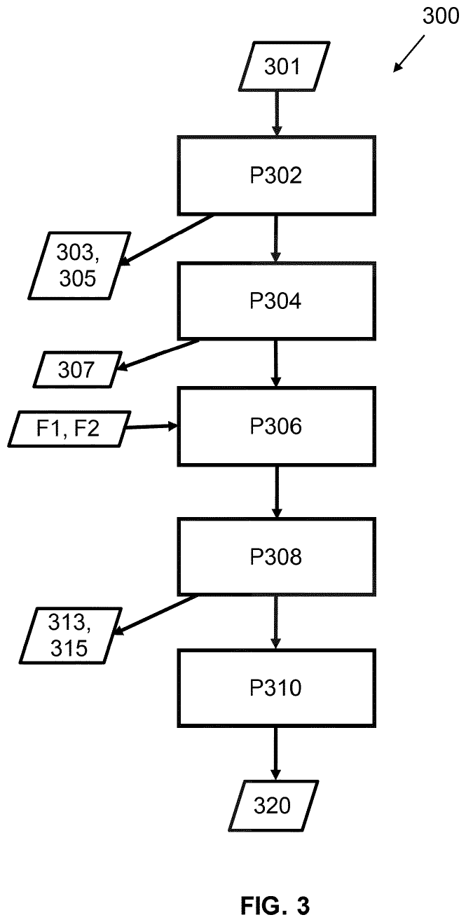

FIG. 3 is a flow chart of an exemplary method of generating rounded contours according to an embodiment of the present disclosure, for example, rounded contour of target contours (e.g., contours in a design layout) desired to be printed on a substrate (e.g., a semiconductor chip), mask patterns, or other lithographic related contours, according to an embodiment. In an embodiment, rounded contours may be used as initial starting point for determining a mask design. In an embodiment, the target contours, mask contours, or other contours may be represented as polygon shapes e.g., in GDSII format. However, the present disclosure is not limited to rounding contours of polygons. In an embodiment, the contours may be two dimensional (2D) representations that can be further converted into another representation (e.g., 1D representations). In some embodiments, filters may be applied to the converted representation to generate filtered 1D representations. The filtered representations are combined to generate rounded contours of the target contours. In an embodiment, the method 300 may be implemented as processes P302, P304, P306, P308, and P310, further discussed in detail below.

Process P302 involves converting a contour representation 301 (e.g., of a mask pattern, target pattern, etc.) to a first set of contour point locations 303 in a first dimension and a second set of contour point locations 305 in a second dimension different from the first dimension. For example, the first set of contour point locations 303 may be x-coordinates and the second set of contour point locations 305 may be y-coordinates of a cartesian coordinates. A person of ordinary skilled in the art can understand that the present disclosure is not limited to any particular coordinate system.

In an embodiment, converting the contour representation 301 involves sampling a plurality of points on the contour representation 301. The plurality of points may be converted to the first set of contour point locations 303 in the first dimension; and to the second set of contour point locations 305 in the second dimension. In an embodiment, converting of the contour representation 301 involves determining a first gradient based on the first set of contour point locations 303 in the first dimension, and a second gradient based on the second set of contour point locations 305 in the second dimension.

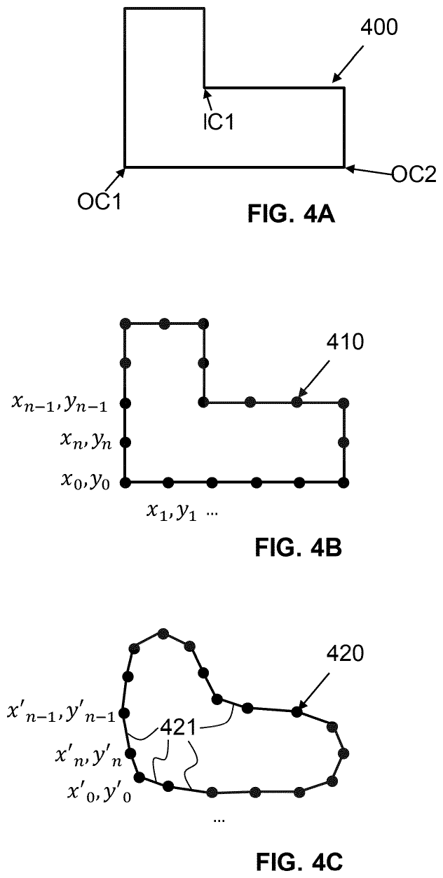

FIG. 4A illustrates an exemplary contour representation of a contour 400 to be printed on a substrate, according to an embodiment. In FIG. 4A, the contour 400 is a two-dimensional representation of an L-shaped polygon with several corners. The contour 400 is represented as a polygon shape (e.g., GDSII format). In an embodiment, the contour 400 includes inner corners ICI, and outer corners OC1 and OC2. Assuming the contour 400 is traversed in a counter-clockwise around the boundary of the polygon (so that the interior of the polygon is always on a left side), at a given corner, if a traveler makes a left turn, that corner is said to be an outer corner and if the traveler makes a right turn, the corner is said to be an inner corner. In an embodiment, the corners, edges, or both corners and edges of the contour 400 may be rounded. The rounding of the contour 400 may be performed using processes as discussed below.

FIG. 4B illustrates an exemplary conversion of the contour representation 400 into a set of contour point locations. In an embodiment, a plurality of points may be sampled along the L-shaped polygon. For example, the plurality of points are illustrated by x, y coordinates (x₀, y₀), (x₁, y₁), . . . , (xₙ, yₙ). In the present example, a converted representation 410 of the contour 400 correspond to the x-coordinates and y-coordinates of the contour 400. The conversion of the contour 400 starts at (x₀, y₀) and travels in a counter-clockwise around the contour 400. Also, since the contour 400 is a closed curve, the converted representation as a function of a parameter s, where s indicates a length along the boundary between two points of the plurality of points. In FIG. 4B, n-sampled points in the first dimension may be represented as a set X={x₀, x₁, . . . , xₙ₋₁, xₙ}, and the n-sampled points in the second dimension may be represented as a set Y={y₀, y₁, . . . , yₙ₋₁, yₙ}. In another example, the conversion of the contour representation 400 may be represented as X={x₀-x₁, x₁-x₂, . . . , xₙ₋₁-xₙ, xₙx₀} and Y={y₀-y₁, y₁-y₂, . . . , yₙ₋₁-yₙ, yₙ-y₀}.

Thus, according to the present disclosure, the conversion of the contour representation is not limited to corners; rather the entire contour, or part of it, may be converted to a set of contour point locations. Such conversion enables continuous and smooth rounding of the contours instead of limiting the rounding to corners. Note that the present conversion into a coordinate-based representation of the original contour representation (e.g., 400) may not be dependent on a parametric representation. In a parametric representation, a parametric equation is used to define a curve or a line as a function of some independent quantities called parameters (e.g., time, angle, or other user defined parameters). In such parametric representation the degree of freedom available for any modification is limited to the parameters. As such, any resulting rounding of the contours based on such parametric representation will be dependent on the parameter values itself. Changes in the parameter values will result in different rounding of the contours and thereby different rounding effects. On the other hand, the rounding of the contours according to the present disclosure is not limited by parameter values.

Process P304 involves determining a signal function 307 based on the first set 303 and the second set 305 of contour point locations. In an embodiment, the signal function 307 indicates different segments (e.g., an edge, an inner corner, an outer corner, etc.) of the contour representation 301. In an embodiment, determining of the signal function 307 involves computing a product of a first difference between two consecutive points in the first set of contour point locations 303 and a second difference between two consecutive points in the second set of contour point locations 305. The present disclosure is not limited to difference-based computation to generate the signal function. For example, the signal function 307 may be computed using other mathematical operation such as a differential, integral, summation, etc. between the first set of contour point locations 303 and/or between the second set of contour point locations 305, where such operation reveals different types of corners.

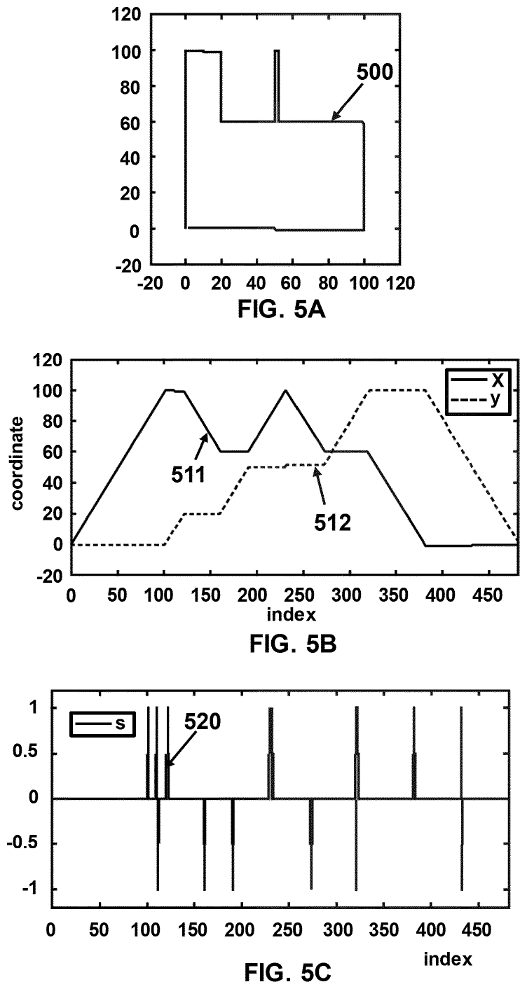

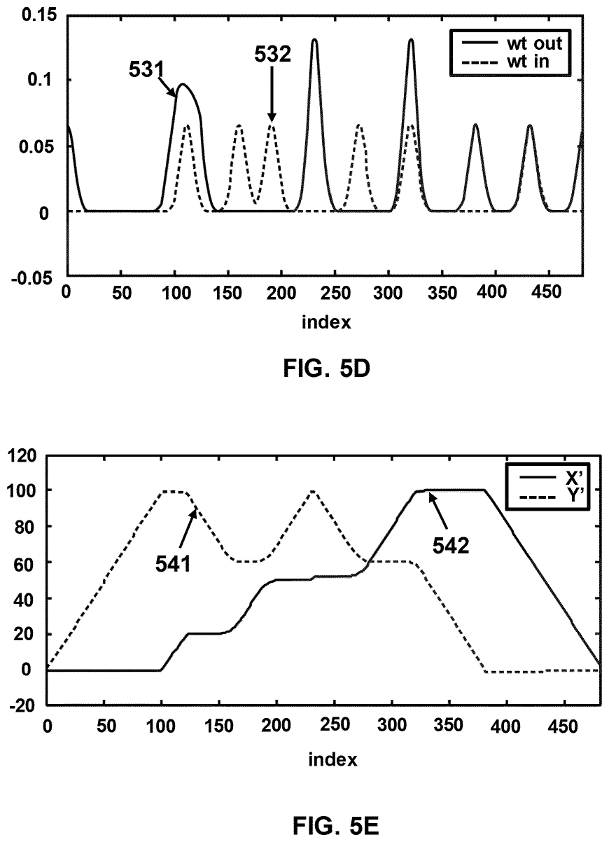

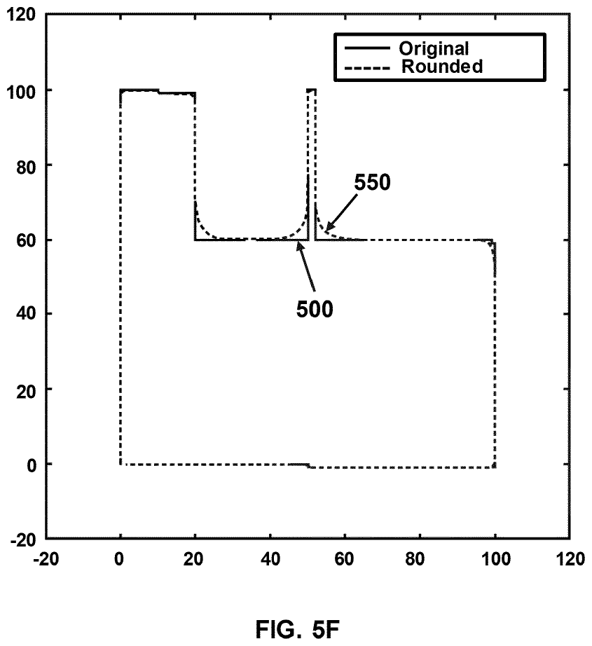

In an embodiment, the signal function 307 may include a first function having values greater than zero, the first function characterizing a first type of corners in the contour representation 301. The signal function 307 may further include a second function having values lower than zero, the second function characterizing a second type of corners in the contour representation 301. In an embodiment, the first function indicates an inner corner of the contour representation 301, and a second function indicates an output corner within the contour representation 301, the inner corner or the outer corner characterizing a corner orientation within the contour representation 301. An example of the signal function 307 is illustrated in FIG. 5C discussed later in the disclosure.

As an example, the signal function 307 may be represented as S[n], which may be computed using the equation below:

$$S [ n ] = ( x [ n ] - x [ n - 1 ] ) \cdot ( y [ n ] - y [ n + 1 ] ) - ( y [ n ] - y [ n - 1 ] ) \cdot ( x [ n ] - x [ n + 1 ] )$$

Based on the computation above, the signal function S may be represented as a set S={s₀, s₁, . . . , sₙ₋₁, sₙ}. In an embodiment, the signal function 307 may be further divided into a first function, a second function, and/or a third function corresponding to a geometric shape of the contour 400. For example, the signal function 307 may be expressed as below:

$$S 1 : S > 0 , indicates an inner corner of the contour representation$$

$$S 2 : S = 0 , indicates an edge of the contour representation$$

$$S 3 : S < 0 , indicates an outer corner of the contour representation$$

The corner locations represented by the S function are smoothed by applying one or more filters or smoothing functions. In some embodiments, the inner and outer corners are smoothed by using the same smoothing function or filters. In some embodiments, the inner corners and the outer corners can be treated in different manners, e.g., by applying different filters. In some embodiments, filtering may vary with the corner angles.

Process P306 involves generating (i) a first set of weights corresponding to the first set of contour point locations 303 by applying a first filter function F1 to the signal function 307, and (ii) a second set of weights corresponding to the second set of contour point locations 305 by applying a second filter to the signal function 307. In an embodiment, the first filter function F1 may include one or more filters such as Gaussian filters, and/or low pass filters. In an embodiment, applying the first filter function F1 involves applying a first filter (e.g., G₁) to the first function (e.g., S1) of the signal function 307 to generate a first weight; and applying a second filter (e.g., G₂) to the second function (e.g., S3) of the signal function 307 to generate a second weight. In an embodiment, the second filter may be same or different from the first filter. For example, a first set of weights WT₁ may be generated by applying a filter G₁ to the signal function 307 having values greater than zero, expressed as WT₁=(S>0)⊗G₁. Similarly, a second set of weights WT₂ may be generated by applying a filter G₂ to the signal function 307 having values less than zero, expressed as WT₂=(S<0)⊗G₂. In an embodiment, the operator ⊗ indicates a summation operation between the signal function S(n) and the filter G. For example, the operator ⊗ may be expressed as ΣₙSₙ·Gᵢ₋ₙ and applied at each point i=0 . . . n.

In an embodiment, a set of weights (e.g., WT₁, WT₂, WT₃, and WT₄) may be determined for different portions (e.g., inner corner or outer corner) of the contour by applying different filters to each of the portions. An example of the weights generated by applying the filter is illustrated in FIG. 5D, discussed later.

Process P308 involves updating (i) the first set of contour point locations based on the first filter function and the signal function 307, and (ii) the second set of contour point locations based on the second filter function and the signal function 307. In an embodiment, (i) the first set of contour point locations 303 is updated based on the first filter function F1 (e.g., G₁, and G₂) and the first set of weights (e.g., WT₁, and WT₂), and (ii) the second set of contour point locations 305 is updated based on the second filter function F2 (e.g., G₃, and G₄) and the second set of weights (e.g., WT₃, and WT₄). The updating process generates an updated first set of contour point locations 313 corresponding to the first set of contour point locations 303, and an updated second set of contour point locations 315 corresponding to the first set of contour point locations 305. In an embodiment, the updating process may involve computing, in the first dimension, a third set of contour points as a function of the first set of contour point locations 303, the first filter function F1, and the first set of weights. The updating process may also involve computing, in the second dimension, a fourth set of contour points as a function of the second set of contour point locations 305, the second filter function F2, and the second set of weights.

In an embodiment, computing in the first dimension involves applying the first filter function F1 (e.g., G₁, and G₂) to contour points of the first set of contour point locations 303 (e.g., x); and applying a weight of the first set of weights (e.g., WT₁, and WT₂) to the filtered contour point. In an embodiment, computing in the second dimension involves applying the second filter function F2 (e.g., G₃, and G₄) to contour points of the second set of contour point locations 305 (e.g., y); and applying a weight of the second set of weights (e.g., WT₃, and WT₄) to the filtered contour point.

For example, updating the first set X and the second set Y of coordinate point locations to coordinates X′ and Y′ may be achieved using the following equation. The updated contour points can be further used to construct the rounded contours.

$${X}^{′} = \{ \begin{matrix}\frac{X ⊗ {G}_{1} * {WT}_{1} + X ⊗ {G}_{2} * {WT}_{2}}{{WT}_{1} + {WT}_{2}} & {WT}_{1} + {WT}_{2} \neq 0 \\ X & {WT}_{1} + {WT}_{2} = 0\end{matrix}$$

$${Y}^{′} = \{ \begin{matrix}\frac{Y ⊗ {G}_{3} * {WT}_{3} + Y ⊗ {G}_{4} * {WT}_{4}}{{WT}_{3} + {WT}_{4}} & {WT}_{3} + {WT}_{4} \neq 0 \\ Y & {WT}_{3} + {WT}_{4} = 0\end{matrix}$$

According to the above equations, computing in the first dimension may involve determining at each point of the first set of contour points whether a sum of weights of the first set of weights at that particular point is equal to zero (e.g., WT₁+WT₂=0). Responsive to the sum not being zero (WT₁+WT₂≠0), a particular point of the first set of contour point locations 303 may be transformed by applying the first filter function F1 (e.g., G₁ and G₂) and taking a weighted average of the filtered point using the first set of weights (e.g., WT₁ and WT₂). In an embodiment, responsive to the sum being zero, the original coordinate point location X may not transformed.

Similarly, computing in the second dimension may involve determining at each point of the second set of contour points whether a sum of weights of the second set of weights at that particular point is equal to zero (WT₃+WT₄=0). Responsive to the sum not being zero (WT₃+WT₄≠0), the particular point of the second set of contour point locations 305 may be transformed by applying the second filter function F2 (e.g., G₃ and G₄) and taking a weighted average of the filtered point using the second set of weights (e.g., WT₃ and WT₄). In an embodiment, responsive to the sum being zero, the original coordinate point location Y may not be transformed.

Process P310 involves generating a rounded contour 320 of the contour representation 301 from the updated first set of contour point locations 313 (e.g., X′) and the updated second set of contour point locations 315 (e.g., Y′). In an embodiment, the rounded contour 320 may be constructed by combining (e.g., plotting) the converted first set and the updated second set of contour point locations to generate a set of 2D contour points; and joining the set of 2D contour points to generate the rounded contour 320 of the contour representation 301. In an embodiment, joining the contour points involves joining adjacent points of the set of 2D contour points by a linear function, a polynomial function or a combination of linear and polynomial functions, to generate an enclosed shape.

FIG. 4C illustrates an example rounded contour 420 from the target contour 400 generated from converted coordinates X′, Y′ coordinates corresponding to the coordinates x, y coordinates of FIG. 4B. As shown, using the method 300, the rounding of an entire contour is achieved. In other words, the rounding is not limited to the corners of the input contour 400 (in FIG. 4A). As an example, points 420 in the converted coordinates X′, Y′ may be plotted as (x₀′, y₀′), (x₁′, y₁′), . . . (xₙ′, yₙ′) in the same sequence as the original coordinates X, Y (in FIG. 4B). The adjacent points in X′, Y′ are joined by a linear curve, or a polynomial curve to generate the rounded contour. For example, the curves may be curved lines or straight lines 421 drawn between two consecutive points. Upon joining all the points (x₀′, y₀′), (x₁′, y₁′), . . . (xₙ′, yₙ′) an enclosed rounded contour 420 is obtained.

In an embodiment, by changing the filter parameters different rounding of the contours may be generated. In an embodiment, by adjusting the filter parameters, an entire contour may be rounded, the rounding may be limited to corners, etc. For example, the filter parameters such as sigma of a Gaussian filter may be adjusted based on different process conditions, geometry of the patterns to be printed on a substrate, a setting of a lithographic apparatus (e.g., aperture, dose, etc.) or other lithography related parameters to determine mask patterns that when employed in lithography produces chips with less defects. In an embodiment, the filter parameters may be calibrated based on contour data associated with a real mask. Such calibration allows filter to implement a more realistic rounding in the design layout.

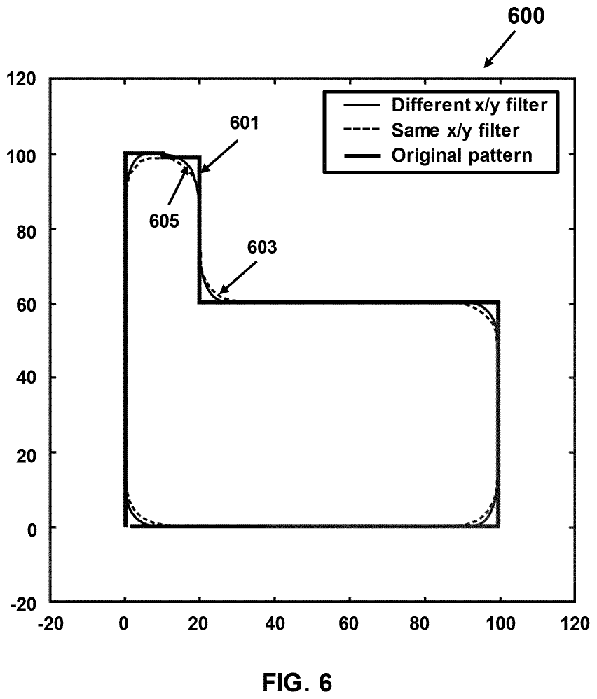

An exemplary implementation of the method 300 is further illustrated with respect to FIGS. 5A-5F and 6. FIG. 5A illustrates an exemplary contour 500 represented as a polygon shape in 2D. The contour has several corners and edges forming an enclosed shape. The contour representation 500 is converted into 1D representations (e.g., according to process P304 of method 300) based on the x-coordinates and y-coordinates of the contour representation 500. For example, FIG. 5B illustrates a first 1D representation 511 generated using the x-coordinates of the contour representation 500, and a second ID representation 512 generated using the y-coordinates of the contour representation 500. The index indicates points along the contour representation 500. As can be seen, the first 1D representation 511 and the second 1D representation 512 may be considered as two orthogonal components of the 2D representation. Separating the 2D contour representation 500 into two components allow processing of the components independently of each other. Thus, more degree of control in rounding a 2D shape may be obtained. It can be understood by a person skill in the art, the present disclosure is not limited to x-y coordinates and other 1D representations in a different coordinate system defined by a user may be used.

FIG. 5C illustrates a signal 520 generated using the first 1D representation 511 and the second 1D representation 512. For example, the signal 520 is generated using the signal function S[n] discussed above. Also, as discussed above, the signal 520 may be used to distinguish different corners and edges in the contour representation 500. For example, values of the signal 520 that are greater than zero (S>0), indicates an inner corner of the contour representation 500, and values of the signal 520 that are less than zero (S<0), indicates an outer corner of the polygon shape 500. It may be advantageous to automatically detect the type of corners (e.g., an inner corner and outer corner) so that different filters may be employed for different types of corners and edges. Additionally, the signal 520 may be used to update the first 1D representation 511 and the second ID representation 512. Thus, the signal 520 can also control an amount of rounding of the contour representation 500. For example, based on the signal different weights may be generated for an inner corner, an outer corner, and edges. Based on the weights associated with different sections of a contour representation 500, different portions of the original 1D representations 511 and 512 may be updated thereby controlling an amount of rounding of different portions of the ID representations 511 and 512 and eventually the final rounding of the original contour representation 500.

FIG. 5D illustrates examples of a first weights 531 for the first 1D representation 511 and a second weights 532 for the second 1D representation 512. The first weights 531 includes values corresponding to different locations (indexes) of the contour representation 500. When these values 531 are applied to corresponding locations of the first 1D representation in the first dimension of the contour representation 500, an updated 1D representation is obtained. For example, the first weights 531 may be applied using the equation X′ discussed above. Similarly, the second weights 532 includes values corresponding to different locations (indexes) of the contour representation 500. When these values 532 are applied to corresponding locations of the second ID representation in the second dimension of the contour representation 500, an updated 1D representation is obtained. For example, the second weights 532 may be applied using the equation Y′ discussed above.

FIG. 5E illustrates the updated 1D representations 531 and 532 of the ID representation 511 and 512, respectively. Upon comparing, it can be seen that the updated ID representation 531 is a rounded version of the 1D representation 511. Similarly, upon comparing, it can be seen that the updated ID representation 532 is a rounded version of the ID representation 512. Further, the updated ID representations are combined to generate the rounded contour.

FIG. 5F illustrates an exemplary rounded contour 550 generated from the updated ID representations 531 and 532. As an example, the combining of updated ID representations 531 and 532 involves plotting (e.g., similar to FIG. 4C) the updated coordinates represented by values of the updated ID representation in two dimensions. Hence, a set of points in the form of updated coordinates is obtained. Further, the points may be joined by a linear or a polygonal line to generate a rounded contour shape. In FIG. 5F, the rounded contour 550 (dotted lines) is overlaid on the original contour representation 500 for comparison. As can be seen, different portions of the original contour 500 are rounded.

FIG. 6 illustrates different rounded contours generated when same or different filters are applied to both ID representations (e.g., in x coordinates, and in y coordinates). A contour representation 600 has straight edges and serval sharp corners (e.g., inner corners and outer corners). The contour rounding process of method 300 may be applied as illustrated in FIGS. 5A-5F. At the process P306 (e.g., illustrated in FIG. 5D), same or different filters may be used to generate weights and further update of the ID representations. When the same filters are used with the 1D representations in both the first dimension (e.g., x) and the second dimension (e.g., y), a first rounded contour 603 is generated. When a first filter is used with a 1D representation in the first dimension (e.g., x) and a different second filter is used with a 1D representation in the second dimension (e.g., y), a second rounded contour 605 is generated. For example, different filters may be generated by changing one or more filter parameters (e.g., sigma of Gaussian) or other contents characterizing the filters. Comparing the contours 603 and 605 shows different curvatures at the corners. Thus, in an embodiment, by controlling the filters the contour rounding may be controlled.

In an embodiment, filters may be developed or tuned based on calibration data obtained from a patterned substrate, the target pattern and corresponding mask patterns used in the patterning process. As characteristics of the patterning process will be reflected in the patterned substrate, such characteristics can be incorporated into the filter parameters. For example, the target pattern may be rounded (according to the method 300) and compared with corresponding features of a mask pattern. Based on the comparison, one or more filter parameter or content may be modified to cause the rounded contour to be within a desired matching threshold with respect to the mask pattern. In this way, the filters can be developed for specific lithographic apparatus and process. For example, a filter may be developed for apparatus having high NA value. Also, the ability to apply different filters to different segments of a contour is advantageous, for example, when particular patterning sub-processes (e.g., related to imaging, resist, etching, etc.) affects corner or other portions of the contour differently during the patterning process.

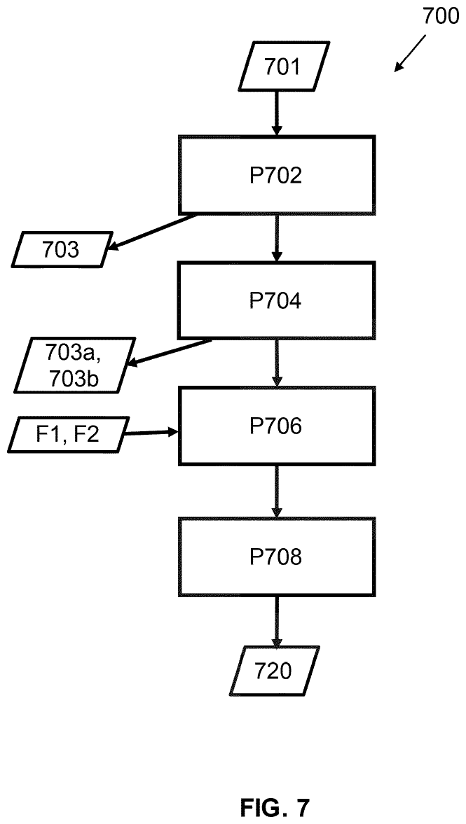

FIG. 7 is a flow chart of a method 700 for generating rounded contours of a pattern, according to another embodiment. In an embodiment, the method 700 may be implemented as processes P702, P704, P706, and P708, further discussed in detail below. The method 700 also provides advantages similar to that of the method 300. For example, according to the method 700, a 2D contour is decomposed into two 1D components and each of these 1D components can be processed separately to generate the rounded contour. In such processing, different corners in the 2D contour may be distinguished from each other and further different filters may be applied to different corners.

Process P702 involves converting a contour representation 701 to one dimensional (1D) representation 703 using a unit directional vector and constraining the 1D representation 703 to satisfy a constrain (e.g., [\vec{u}]=1) that is approximately proportional to the unit direction. For example, the 1D representation 703 may be multiplied by a constant. And when a filter is applied to the 1D representation, the result may be divided by the same constant. In an embodiment, the constrain is a unity constraint, which is indicative of a closed path of the unit directional vector. In an embodiment, converting of the contour representation 701 involves selecting a starting point on the contour representation 701; and transforming an enclosed shape (e.g., a partially or fully enclosed shape) of the contour representation 701 into a straight line by unfolding the contour representing from the starting point.

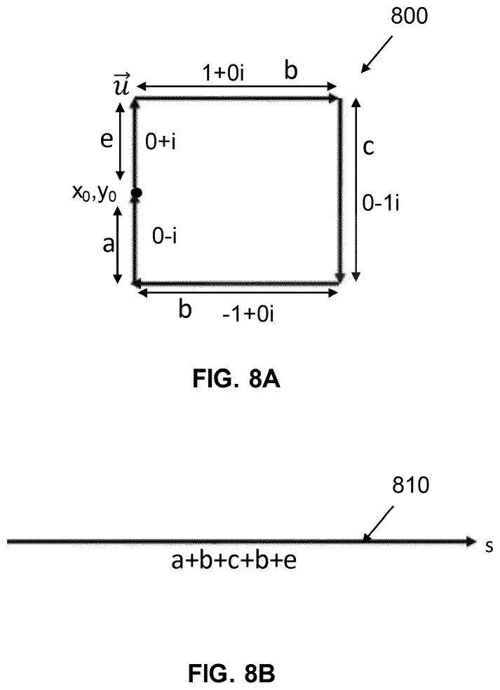

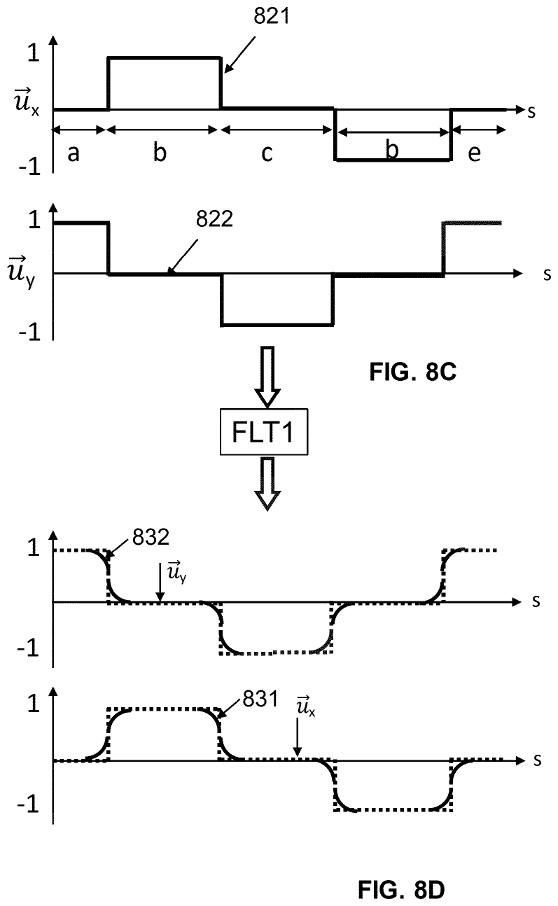

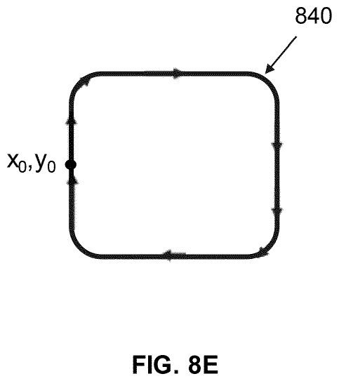

For example, FIG. 8A illustrates a contour representation 800 and FIG. 8B illustrates the 1D representation upon unfolding the contour 800 into a single dimension “s.” In FIG. 8A, a starting point (x₀, y₀) is selected and a unit direction vector \vec{u} is drawn along the contour indicating a direction of travel along the contour 800. For example, a unit direction (0+i) indicates an upward vertical direction, (1+0i) indicates a horizontal direction towards right, (0−1i) indicates a downward vertical direction, (−1+0i) indicates a horizontal direction towards left, and (0−i) indicates a vertical upward direction towards the starting point. Thus, using the unit direction vector an entire contour may be traversed. In an embodiment, a length or magnitude of an edge along the respective unit direction may be used to unfold the contour 800 to generate the 1D representation 810 (see FIG. 8B). For example, a, b, c, d, and e indicate the lengths of the segments of the contour representation 800. The contour representation 800 is illustrated as having a rectangular shape, however, the present disclosure is not limited to a such shape. As another example, the contour representation 800 may be a curved shape contour and the unit directional vector may be drawn at a plurality of points along the contour to generate the 1D representations.

Process P704 involves determining (i) a first function 703a (e.g., \vec{u}ₓ) of the 1D representation 703 by taking a gradient of the 1D representation 703 with respect to a first dimension (e.g., x); and (ii) a second function 703b (e.g., \vec{u}_{y}) of the ID representation 703 by taking another gradient of the 1D representation 703 with respect to a second dimension (e.g., y). The first function 703a and the second function 703b each also satisfy the constrain that is proportional to the unit direction. In an embodiment, the constraint is represented by |\vec{u}|=1, which is collectively satisfied by the components 703a and 703b of the contour representation. For example, FIG. 8C illustrates a first function 821 in the first dimension and a second function 822 in the second dimension.

In an embodiment, the process P704 may further involve distinguishing different segments (e.g., corners, edges) of the contour representation 701. In an embodiment distinguishing the corners may be achieved by performing an operation on the first function 703a and the second function 703b. For example, computing a signum function of the first function 703a and the second function 703b of the 1D representation 703 generates a positive value that indicates the first type of corner (e.g., an inner corner), and a negative value that indicates the second type of corner (e.g., an outer corner). In an embodiment, for example, for curved contours, a sine of the unit function may be used to distinguish between different types of corners. For example, sin(du)/ds may be computed to distinguish between different corners of a curved contour. In other words, a sine function is applied to change in unit vector \vec{u}. Since \vec{u} is a unit vector, change in \vec{u} is an angle. The present approach of distinguishing between corners may be applied to any type of pattern such as Manhattan patterns, or curvilinear patterns.

In an embodiment, determining of the first function 703a of the 1D representation 703 involves generating a first unit step function in the first dimension based on a length of segments of the contour representation 701 in the first dimension and the second dimension, and in a direction of traverse along the contour representation 701. For example, see the first function 821 in FIG. 8C. In an embodiment, the first function 703a of the 1D representation 703 may be determined by computing a cosine function along the contour representation 701 using an angle between edges in the contour representation 701.

In an embodiment, determining of the second function 703b of the 1D representation 703 involves generating a second unit step function in the second dimension based on the lengths of segments of the contour representation 701 in the first dimension and the second dimension, and in a direction of traverse along the contour representation 701. For example, see the second function 822 in FIG. 8C. In an embodiment, the second function 703b of the 1D representation 703 may be determined by computing a sine function along the contour representation 701 using an angle between edges in the contour representation 701.

Process P706 involves filtering a first function 703a with a first filter F1 to obtain a filtered function and a second function 703b with a second filter F2 to obtain another filtered function. For example, applying a filter includes convoluting. In an embodiment, the process P706 involves generating (i) a first filtered function by convoluting the first function 703a with the first filter F1, and (ii) a second filtered function by convoluting the second function 703b with the second filter F1. In an embodiment, the first filtered function may be generated by convoluting the first function 703a with the first filter F1 causing at least a portion of a shape represented by the first function 703a to be rounded. In an embodiment, the second filtered function may be generated by convoluting the second function 703b with the second filter causing at least a portion of a shape represented by the second function 703b to be rounded.

FIG. 8D illustrates that when the first function 703a (e.g., \vec{u}ₓ) is convoluted with the filter FLT1, a first filtered function 831 is generated. As an example, the filter FLT1 may be a Gaussian filter or a low pass filter. Similarly, when the second function 703b (e.g., \vec{u}_{y}) is convoluted with the filter FLT1, a second filtered function 832 is generated. As shown in FIG. 8D, the filtered functions 831 and 832 are each rounded compared to the pre-filtered functions 821 and 822, respectively. As mentioned earlier, the present disclosure is not limited to use of the same filters in the first and second dimensions. In an embodiment, different filters may be applied for different segments of the contour representation 800. For example, upon distinguishing of different segments (e.g., the inner corners and the outer corners) of the contour representation, a first filter may be applied to the inner corners and a second filter may be applied to the second corners. To clarify, in some embodiments, inner and outer corners are not distinguished by applying different filters. However, differential treatment of two components (e.g., x and y of the contour representation) may be beneficial, for example, in EUV, since x and y axes may be treated differently due to oblique incidence of light on a substrate caused by mirrors used in EUV. In an embodiment, such differential treatment may not be caused by mask making process. Thus, in an embodiment, differential treatment of two components (e.g., x and y) may advantageously compensate for inaccuracies in mask corner modeling.

In an embodiment, generating of the first filtered function and the second filtered function involve constraining the generation step to satisfy a first condition that absolute value of the unit vector convoluted with the first and second filter functions is unity or other constrain. The first condition may be expressed as |\vec{u}*f|=1, where * indicates a convolution operation, \vec{u} is the unit vector comprising the 1D representations in the first dimension and the second dimension, and f comprises the first filter F1 and the second filter F2. In an embodiment, the filtered functions may be normalized based on the magnitude of a convolution between the unit vector and the respective filter. For example, the filtered function may be expressed as (\vec{u}*f)/|\vec{u}*f|.

In an embodiment, generating of the first filtered function and the second filtered function involves constraining the generation operation to satisfy a second condition that a steady state response to a unit step function is unity. The second condition may be expressed as ∫\vec{u}*f ds=0, where * indicates a convolution operation, \vec{u} is the unit vector comprising the ID representations in the first dimension and the second dimension, and f comprises the first filter F1 and the second filter F2.

In an embodiment, \vec{u} may represents one period of a complex periodic function. A filter f will be applied to the periodic function that is generated by repeating \vec{u}. Accordingly, one period of the resulting periodic function will be used to generate the rounded pattern.

Process P708 involves generating a rounded contour 720 for the mask pattern by combining the first filtered function and the second filtered function of the contour representation 701. In an embodiment, the first filtered function may be generated using the filter function for the first type of corners (e.g., the inner corners) and the other filter function for the second type of corners (e.g., the outer corners). In an embodiment, generating the rounded contour 720 involves integrating the first filtered function along a length of the 1D representation 703; integrating the second filtered function along a length of the 1D representation 703; and combining the integrated functions to generate the rounded contour 720.

FIG. 8E illustrates a rounded contour 840 of the contour representation 800 (in FIG. 8A). The rounded contour 840 may be generated by combining the first filtered function 831 and the second filtered function 832 over the length s of the contour representation 800. While the functions 831 and 832 are combined, it is ensured that path of the unit direction vector (in FIG. 8A) is followed to generate the enclosed rounded contour corresponding to the contour representation 800.

In an embodiment, rounded contour may be centered with respect to the original contour representation 701. For example, a center of the rounded contour 720, and a center of the contour representation 701 is determined and the centers of the rounded contour 720 and the contour representation 701 are aligned with each other. In an embodiment, the center of original contour and a contour obtained post filtering may be centered to the same point.

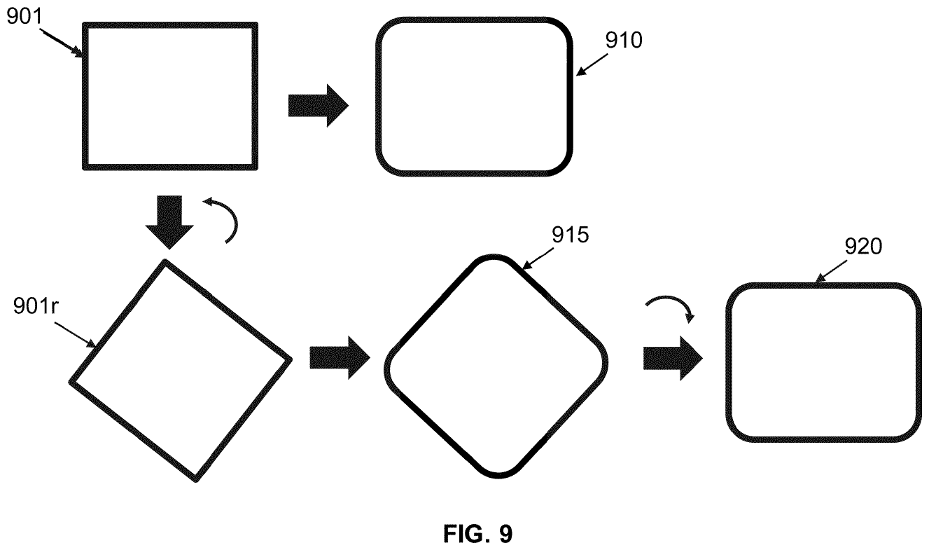

FIG. 9 illustrates that rounded contours obtained according to the present disclosure may be advantageously not affected by rotation of the contours. In a first case, a contour 901 may be used to generate a rounded contour 910 by applying the method 700. In a second case, the contour 901 may be rotated in a counter-clockwise direction by an amount θ to obtain the rotated contour 901r. This rotated contour 901r may be used to generate another rounded contour 915 by applying the same method 700. When the rounded contour 901r is rotated back to original position by rotating it in clockwise direction by the same amount θ, the rounded contour 920 is obtained. Comparing the rounded contour 920 and 910 shows that these rounded contours are the same or substantially the same.

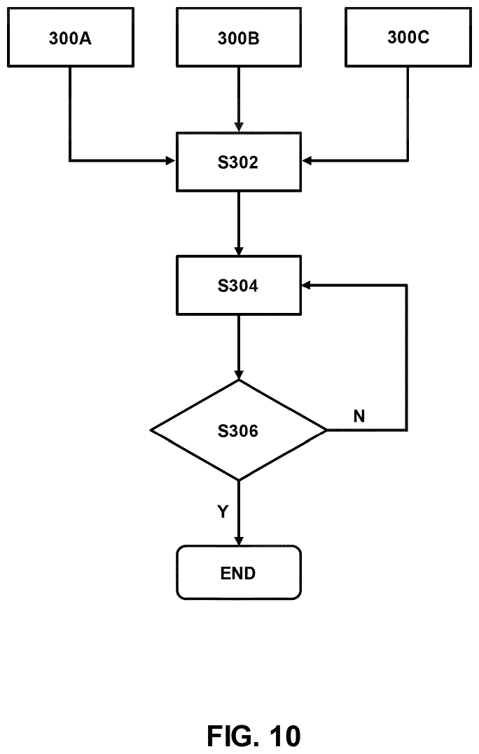

The methods herein may further involve processes for generating a mask design based on the rounded contour of the contour representation. For example, the method 300 or 700 may be integrated into a mask design process (e.g., SMO, OPC, etc. discussed in FIGS. 10-13) to generate a mask pattern corresponding to a design layout.

In an embodiment, generating of the mask design involves (a1) accessing a design layout comprising a plurality of contour representation; (b1) generating rounded contours for the each of the plurality of the contour representations using the method 300 or 700; (c1) simulating a patterning process (e.g., according to method in FIG. 2) using the rounded contours to generate simulated contours associated with a semiconductor chip; (d1) obtaining printed contours of a patterned substrate patterned using a mask associated with the design layout; (e1) determining whether the simulated contours and the printed contours are within a matching threshold; and (f1) responsive to the simulated contours not matching the printed contours, adjusting parameters of the one or more filters and repeating steps (a1)-(f1).

In an embodiment, the methods 300 and 700 may be further extended to determine whether design constraints are satisfied by simulated contours of a substrate. In an embodiment, the processes involve (a2) accessing a design layout comprising a plurality of contour representation; (b2) generating rounded contours for the each of the plurality of the contour representation using the method 300 or 700; (c2) simulating, using the rounded contours, an optimal proximity correction process (e.g., according to methods in FIGS. 10-13) to generate simulated contours associated with a substrate; (d2) determining whether the simulated contours satisfy design specifications; and (e2) responsive to the simulated contours not satisfying the design specification, adjusting the design layout, and repeating steps (a2)-(e2).

In an embodiment, the methods 300 and 700 may be further extended to determine whether mask rule check (MRC) conditions are satisfied. In an embodiment, the processes involve (a3) accessing a design layout comprising a plurality of contour representation; (b3) generating rounded contours for the each of the plurality of the contour representation using the method 300 or 700; (c3) simulating, using the rounded contours, an optimal proximity correction process (e.g., according to methods in FIGS. 10-13) to generate mask patterns; (d3) determining whether the mask patterns satisfy mask rule check (MRC) conditions; and (e3) responsive to the mask patterns not satisfying the MRC, adjusting the design layout, and repeating steps (a3)-(e3).

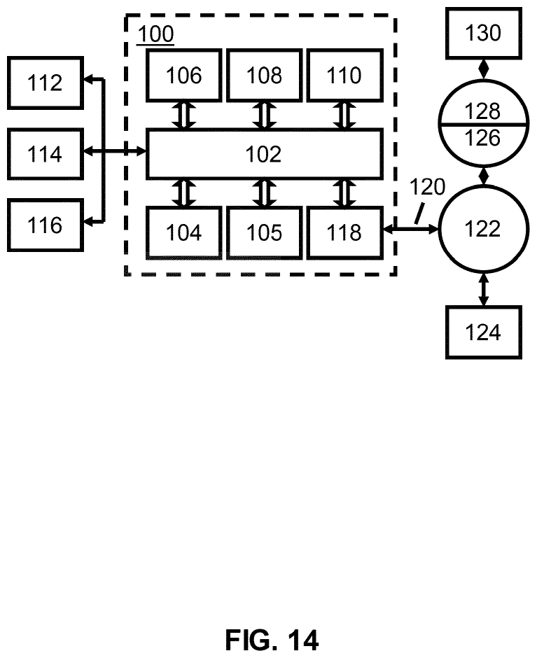

In an embodiment, the methods discussed herein may be provided as one or more computer program products or a non-transitory computer readable medium having instructions recorded thereon, the instructions when executed by a computer implementing the operation of the method 300 or 700 discussed above. For example, an example computer system CS in FIG. 14 includes a non-transitory computer-readable media (e.g., memory) comprising instructions that, when executed by one or more processors (e.g., 104), cause operations for determining rounded contours. According to present disclosure, the combination and sub-combinations of disclosed elements constitute separate embodiments.

Examples of mask optimization process including OPC process are further discussed in detail with respect to FIGS. 10-13. These mask optimization processes can be modified as discussed with respect to the method 900 to enable mask design. In an embodiment, the mask optimization process involves computing a cost function as a function of parameters associated with the lithographic process, and a mask. For example, the mask features may be represented as design variables, as discussed herein. These design variables will be affected due to changes based on the MRC violations detected by the detectors.

According to present disclosure, the combination and sub-combinations of disclosed elements constitute separate embodiments. For example, a first combination includes obtaining a detector, and determining MRC violations associated with mask features. The sub-combination may include the detector being a particular enclosed shape and size based on the mask feature, where MRC violations occur when a portion of the mask feature is inside the detector. In another sub-combination, the detector may be circular, or a non-circular shape. In another example, the combination includes determining a mask design based on a detector identified MRC violations. The detector having a non-circular shape that detects width, space and/or curvature violations.

In a lithographic process, as an example, a cost function may be expressed as

$$CF ( {z}_{1} , {z}_{2} , … , {z}_{N} ) = {Σ}_{p = 1}^{P} {w}_{p} {f}_{p}^{2} ( {z}_{1} , {z}_{2} , … , {z}_{N} ) \qquad ( Eq . 1 )$$

wherein (z₁, z₂, . . . , z_{N}) are N design variables or values thereof. fₚ(z₁, z₂, . . . , z_{N}) can be a function of the design variables (z₁, z₂, . . . , z_{N}) such as a difference between an actual value and an intended value of a characteristic at an evaluation point for a set of values of the design variables of (z₁, z₂, . . . , z_{N}). wₚ is a weight constant associated with fₚ(z₁, z₂, . . . , z_{N}). An evaluation point or pattern more critical than others can be assigned a higher wₚ value. Patterns and/or evaluation points with larger number of occurrences may be assigned a higher wₚ value, too. Examples of the evaluation points can be any physical point or pattern on the substrate, any point on a virtual design layout, or resist image, or aerial image, or a combination thereof. CF (z₁, z₂, . . . , z_{N}) can be a function of the illumination source, a function of a variable that is a function of the illumination source or that affects the illumination source. Of course, CF(z₁, z₂, . . . , z_{N}) is not limited to the form in Eq. 1. CF (z₁, z₂, . . . , z_{N}) can be in any other suitable form.

The cost function may represent any one or more suitable characteristics of the lithographic projection apparatus, lithographic process or the substrate, for instance, focus, CD, image shift, image distortion, image rotation, stochastic variation, throughput, local CD variation, process window, or a combination thereof. In one embodiment, the design variables (z₁, z₂, . . . , z_{N}) comprise one or more selected from dose, global bias of the patterning device, and/or shape of illumination. In one embodiment, the design variables (z₁, z₂, . . . , z_{N}) comprise the bandwidth of the source. Since it is the resist image that often dictates the pattern on a substrate, the cost function may include a function that represents one or more characteristics of the resist image. For example, fₚ(z₁, z₂, . . . , z_{N}) of such an evaluation point can be simply a distance between a point in the resist image to an intended position of that point (i.e., edge placement error EPEₚ(z₁, z₂, . . . , z_{N})). The design variables can include any adjustable parameter such as an adjustable parameter of the source (e.g., the intensity, and shape), the patterning device, the projection optics, dose, focus, etc.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the evaluation points and the cost function. Such changes can be simulated from a model or actually measured.

The design variables may have constraints, which can be expressed as (z₁, z₂, . . . , z_{N})∈z, where z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput. In an embodiment, the constraints on the design variables are such that the design variables cannot have values that change any geometrical characteristics of the patterning device-namely, the patterns on the patterning device will remain unchanged during the optimization.

The optimization process therefore is to find a set of values of the one or more design variables, under the constraints (z₁, z₂, . . . , z_{N})∈z, that optimize the cost function, e.g., to find:

$$( {\tilde{z}}_{1} , {\tilde{z}}_{2} , … , {\tilde{z}}_{N} ) = arg {min}_{( {z}_{1} , {z}_{2} , … , {z}_{N} ) ∈ Z} CF ( {z}_{1} , {z}_{2} , … , {z}_{N} ) \qquad ( Eq . 2 )$$

A general method of optimizing, according to an embodiment, is illustrated in FIG. 10. This method comprises a step S302 of defining a multi-variable cost function of a plurality of design variables. The design variables may comprise any suitable combination selected from design variables representing one or more characteristics of the illumination (300A) (e.g., pupil fill ratio, namely percentage of radiation of the illumination that passes through a pupil or aperture), one or more characteristics of the projection optics (300B) and/or one or more characteristics of the design layout (300C). For example, the design variables may include design variables representing one or more characteristics of the illumination (300A) (e.g., being or including the bandwidth) and of the design layout (300C) (e.g., global bias) but not of one or more characteristics of the projection optics (300B), which leads to an illumination-patterning device (e.g., mask) optimization (“source-mask optimization” or SMO). Or, the design variables may include design variables representing one or more characteristics of the illumination (300A) (optionally polarization), of the projection optics (300B) and of the design layout (300C), which leads to an illumination-patterning device (e.g., mask)-projection system (e.g., lens) optimization (“source-mask-lens optimization” or SMLO). Or the design variables may include design variables representing one or more characteristics of the illumination (300A) (e.g., being or including the bandwidth), one or more non-geometrical characteristics of the patterning device, or one or more characteristics of the projection optics (300B), but not any geometrical characteristics of the patterning device. In step S304, the design variables are simultaneously adjusted so that the cost function is moved towards convergence. In an embodiment, not all design variables may be simultaneously adjusted. Each design variable may also be adjusted individually. In step S306, it is determined whether a predefined termination condition is satisfied. The predetermined termination condition may include various possibilities, e.g., one or more selected from: the cost function is minimized or maximized, as required by the numerical technique used, the value of the cost function is equal to a threshold value or crosses the threshold value, the value of the cost function reaches within a preset error limit, and/or a preset number of iterations is reached. If a condition in step S306 is satisfied, the method ends. If the one or more conditions in step S306 is not satisfied, the steps S304 and S306 are iteratively repeated until a desired result is obtained. The optimization does not necessarily lead to a single set of values for the one or more design variables because there may be a physical restraint, caused by a factor such as pupil fill factor, resist chemistry, throughput, etc. The optimization may provide multiple sets of values for the one or more design variables and associated performance characteristics (e.g., the throughput) and allows a user of the lithographic apparatus to pick one or more sets.

Different subsets of the design variables (e.g., one subset including characteristics of the illumination, one subset including characteristics of patterning device and one subset including characteristics of projection optics) can be optimized alternatively (referred to as Alternative Optimization) or optimized simultaneously (referred to as Simultaneous Optimization). So, two subsets of design variables being optimized “simultaneously” or “jointly” means that the design variables of the two subsets are allowed to change at the same time. Two subsets of design variables being optimized “alternatively” as used herein means that the design variables of the first subset but not the second subset are allowed to change in the first optimization and then the design variables of the second subset but not the first subset are allowed to change in the second optimization.

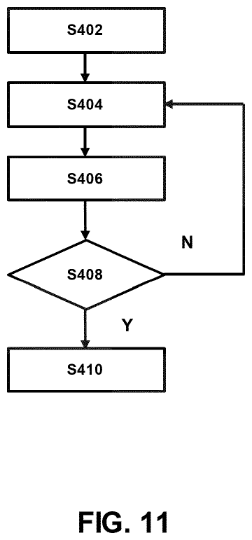

In FIG. 10, the optimization of all the design variables is executed simultaneously. Such a flow may be called simultaneous flow or co-optimization flow. Alternatively, the optimization of all the design variables is executed alternatively, as illustrated in FIG. 11. In this flow, in each step, some design variables are fixed while other design variables are optimized to optimize the cost function; then in the next step, a different set of variables are fixed while the others are optimized to minimize or maximize the cost function. These steps are executed alternatively until convergence or a certain terminating condition is met. As shown in the non-limiting example flowchart of FIG. 11, first, a design layout (step S402) is obtained, then a step of illumination optimization is executed in step S404, where the one or more design variables (e.g., the bandwidth) of the illumination are optimized (SO) to minimize or maximize the cost function while other design variables are fixed. Then in the next step S406, a projection optics optimization (LO) is performed, where the design variables of the projection optics are optimized to minimize or maximize the cost function while other design variables are fixed. These two steps are executed alternatively, until a certain terminating condition is met in step S408. One or more various termination conditions can be used, such as the value of the cost function becomes equal to a threshold value, the value of the cost function crosses the threshold value, the value of the cost function reaches within a preset error limit, a preset number of iterations is reached, etc. Note that SO-LO-Alternative-Optimization is used as an example for the alternative flow. As another example, a first illumination-patterning device co-optimization (SMO) or illumination-patterning device-projection optics co-optimization (SMLO) can be performed without allowing the bandwidth to change, followed by a second SO or illumination-projection optics co-optimization (SLO) allowing the bandwidth to change. Finally, the output of the optimization result is obtained in step S410, and the process stops.

The pattern selection algorithm, as discussed before, may be integrated with the simultaneous or alternative optimization. For example, when an alternative optimization is adopted, first a full-chip SO can be performed, one or more ‘hot spots’ and/or ‘warm spots’ are identified, then a LO is performed. In view of the present disclosure numerous permutations and combinations of sub-optimizations are possible in order to achieve the desired optimization results.

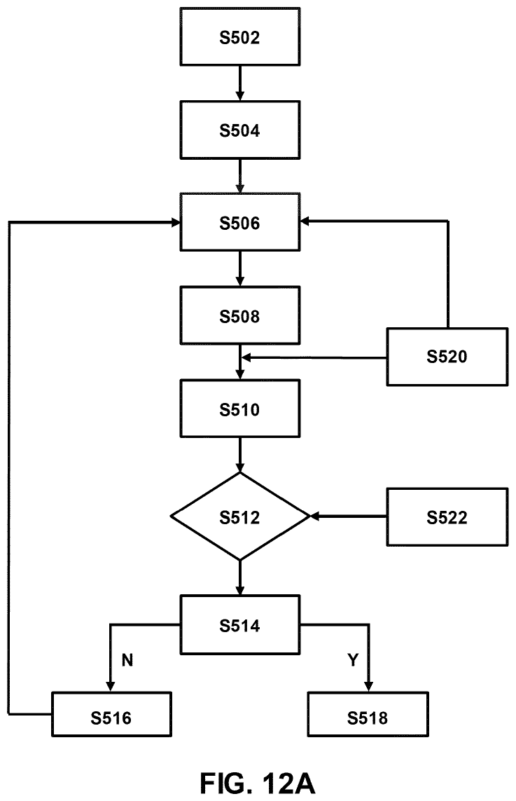

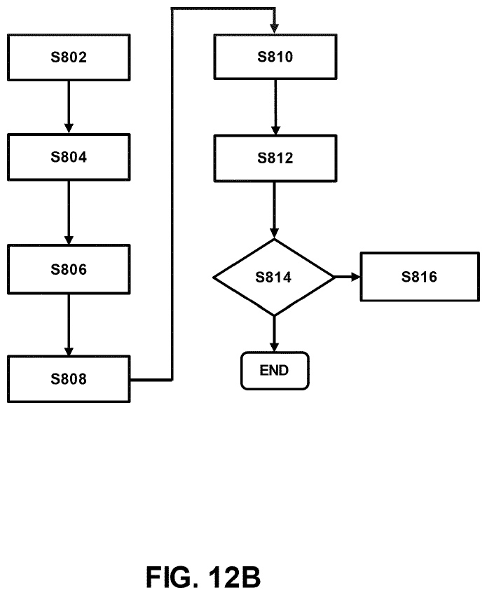

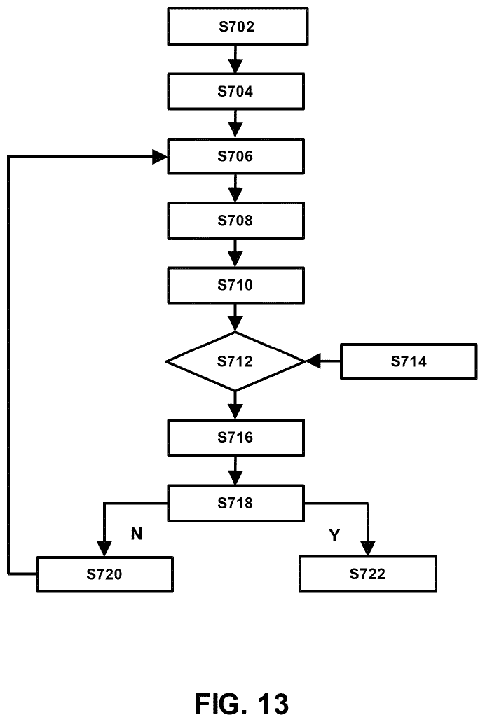

FIG. 12A shows one exemplary method of optimization, where a cost function is minimized or maximized. In step S502, initial values of one or more design variables are obtained, including one or more associated tuning ranges, if any. In step S504, the multi-variable cost function is set up. In step S506, the cost function is expanded within a small enough neighborhood around the starting point value of the one or more design variables for the first iterative step (i=0). In step S508, standard multi-variable optimization techniques are applied to the cost function. Note that the optimization problem can apply constraints, such as the one or more tuning ranges, during the optimization process in S508 or at a later stage in the optimization process. Step S520 indicates that each iteration is done for the one or more given test patterns (also known as “gauges”) for the identified evaluation points that have been selected to optimize the lithographic process. In step S510, a lithographic response is predicted. In step S512, the result of step S510 is compared with a desired or ideal lithographic response value obtained in step S522. If the termination condition is satisfied in step S514, i.e., the optimization generates a lithographic response value sufficiently close to the desired value, then the final value of the design variables is outputted in step S518. The output step may also include outputting one or more other functions using the final values of the design variables, such as outputting a wavefront aberration-adjusted map at the pupil plane (or other planes), an optimized illumination map, and/or optimized design layout etc. If the termination condition is not satisfied, then in step S516, the values of the one or more design variables is updated with the result of the i-th iteration, and the process goes back to step S506. The process of FIG. 12A is elaborated in detail below.

In an exemplary optimization process, no relationship between the design variables (z₁, z₂, . . . , z_{N}) and fₚ(z₁, z₂, . . . , z_{N}) is assumed or approximated, except that fₚ(z₁, z₂, . . . , z_{N}) is sufficiently smooth (e.g. first order derivatives

$$\frac{\partial {f}_{p} ( {z}_{1} , {z}_{2} , … , {z}_{N} )}{\partial {z}_{n}} ,$$

(n=1, 2, . . . N) exist), which is generally valid in a lithographic projection apparatus. An algorithm, such as the Gauss-Newton algorithm, the Levenberg-Marquardt algorithm, the Broyden-Fletcher Goldfarb-Shanno algorithm, the gradient descent algorithm, the simulated annealing algorithm, the interior point algorithm, and the genetic algorithm, can be applied to find (\tilde{z}₁, \tilde{z}₂, . . . , \tilde{z}_{N}).

Here, the Gauss-Newton algorithm is used as an example. The Gauss-Newton algorithm is an iterative method applicable to a general non-linear multi-variable optimization problem. In the i-th iteration wherein the design variables (z₁, z₂, . . . , z_{N}) take values of (z₁ᵢ, z₂ᵢ, . . . , z_{Ni}), the Gauss-Newton algorithm linearizes fₚ(z₁, z₂, . . . , z_{N}) in the vicinity of (z₁ᵢ, z₂ᵢ, . . . , z_{Ni}), and then calculates values (z₁₍ᵢ₊₁₎, z₂₍ᵢ₊₁₎, . . . , z_{N(i+1)}) in the vicinity of (z₁ᵢ, z₂ᵢ, . . . , z_{Ni}) that give a minimum of CF(z₁, z₂, . . . , z_{N}). The design variables (z₁, z₂, . . . , z_{N}) take the values of (z₁₍ᵢ₊₁₎, z₂₍ᵢ₊₁₎, . . . , z_{N(i+1)}) in the (i+1)-th iteration. This iteration continues until convergence (i.e., CF (z₁, z₂, . . . , z_{N}) does not reduce any further) or a preset number of iterations is reached.

Specifically, in the i-th iteration, in the vicinity of (z₁ᵢ, z₂ᵢ, . . . , z_{Ni}),

$${{f}_{p} ( {z}_{1} , {z}_{2} , … , {z}_{N} ) \approx {f}_{p} ( {z}_{1 i} , {z}_{2 i} , … , {z}_{Ni} ) + {Σ}_{n = 1}^{N} \frac{\partial {f}_{p} ( {z}_{1} , {z}_{2} , … , {z}_{N} )}{\partial {z}_{n}} \vert}_{{z}_{1} = {z}_{1 i} , {z}_{2} = {z}_{2 i} , {…z}_{N = {z}_{Ni}}} ( {z}_{n} = {z}_{ni} ) \qquad ( Eq . 3 )$$

Under the approximation of Eq. 3, the cost function becomes:

$$CF ( {z}_{1} , {z}_{2} , … , {z}_{N} ) = \qquad ( Eq . 4 )$$

$${Σ}_{p = 1}^{P} {w}_{p} {f}_{p}^{2} ( {z}_{1} , {z}_{2} , … , {z}_{N} ) = {Σ}_{p = 1}^{P} {w}_{p} ( {f}_{p} ( {z}_{1 i} , {z}_{2 i} , … , {z}_{Ni} ) +$$

$${{{Σ}_{n = 1}^{N} \frac{\partial {f}_{p} ( {z}_{1} , {z}_{2} , … , {z}_{N} )}{\partial {z}_{n}} \vert}_{{z}_{1} = {z}_{1 i} , {z}_{2} = {z}_{2 i} , {…z}_{N = {z}_{Ni}}} ( {z}_{n} = {z}_{ni} ) )}^{2}$$

which is a quadratic function of the design variables (z₁, z₂, . . . , z_{N}). Every term is constant except the design variables (z₁, z₂, . . . , z_{N}).

If the design variables (z₁, z₂, . . . , z_{N}) are not under any constraints, (z₁₍ᵢ₊₁₎, z₂₍ᵢ₊₁₎, . . . , z_{N(i+1)}) can be derived by solving N linear equations:

$$\frac{\partial CF ( {z}_{1} , {z}_{2} , … , {z}_{N} )}{\partial {z}_{n}} = 0 ,$$

wherein n=1, 2, . . . , N.

If the design variables (z₁, z₂, . . . , z_{N}) are under constraints in the form of J inequalities (e.g. tuning ranges of (z₁, z₂, . . . , z_{N})) Σₙ₌₁^{N} Aₙⱼzₙ≤Bⱼ, for j=1, 2, . . . , J; and K equalities (e.g. interdependence between the design variables) Σ_{N=1}^{N} Cₙₖzₙ≤Dₖ, for k=1, 2, . . . , K, the optimization process becomes a classic quadratic programming problem, wherein Aₙⱼ, Bⱼ, Cₙₖ, Dₖ are constants. Additional constraints can be imposed for each iteration. For example, a “damping factor” Δ_{D}, can be introduced to limit the difference between (z₁₍ᵢ₊₁₎, z₂₍ᵢ₊₁₎, . . . , z_{N(i+1)}) and (z₁ᵢ, z₂ᵢ, . . . , z_{Ni}), so that the approximation of Eq. 3 holds. Such constraints can be expressed as zₙᵢ−Δ_{D}≤zₙ≤zₙᵢ+ΔD. (z₁₍ᵢ₊₁₎, z₂₍ᵢ₊₁₎, . . . , z_{N(i+1)}) can be derived using, for example, methods described in Numerical Optimization (2^{nd} ed.) by Jorge Nocedal and Stephen J. Wright (Berlin New York: Vandenberghe. Cambridge University Press).

Instead of minimizing the RMS of fₚ(z₁, z₂, . . . , z_{N}), the optimization process can minimize magnitude of the largest deviation (the worst defect) among the evaluation points to their intended values. In this approach, the cost function can alternatively be expressed as

$$CF ( {z}_{1} , {z}_{2} , … , {z}_{N} ) = {max}_{1 \leq p \leq P} \frac{{f}_{p} ( {z}_{1} , {z}_{2} , … , {z}_{N} )}{{CL}_{p}} \qquad ( Eq . 5 )$$

wherein CLₚ is the maximum allowed value for fₚ(z₁, z₂, . . . , z_{N}). This cost function represents the worst defect among the evaluation points. Optimization using this cost function minimizes magnitude of the worst defect. An iterative greedy algorithm can be used for this optimization.

The cost function of Eq. 5 can be approximated as:

$$CF ( {z}_{1} , {z}_{2} , … , {z}_{N} ) = {Σ}_{p = 1}^{P} {{w}_{p} ( \frac{{f}_{p} ( {z}_{1} , {z}_{2} , … , {z}_{N} )}{{CL}_{p}} )}^{q} \qquad ( Eq . 6 )$$

wherein q is an even positive integer such as at least 4, or at least 10. Eq. 6 mimics the behavior of Eq. 5, while allowing the optimization to be executed analytically and accelerated by using methods such as the deepest descent method, the conjugate gradient method, etc.

Minimizing the worst defect size can also be combined with linearizing of fₚ(z₁, z₂, . . . , z_{N}). Specifically, fₚ(z₁, z₂, . . . , z_{N}) is approximated as in Eq. 3. Then the constraints on worst defect size are written as inequalities ELₚ≤fₚ(z₁, z₂, . . . , z_{N})≤E_{Up}, wherein ELₚ and EUₚ, are two constants specifying the minimum and maximum allowed deviation for the fₚ(z₁, z₂, . . . , z_{N}). Plugging Eq. 3 in, these constraints are transformed to, for p=1, . . . P,

$${{\sum }_{n = 1}^{N} \frac{\partial {f}_{p} ( {z}_{1} , {z}_{2} , … , {z}_{N} )}{\partial {z}_{n}} \vert}_{{z}_{1} = {z}_{1 i} , {z}_{2} = {z}_{2 i} , {…z}_{N = {z}_{Ni}}} {z}_{n} \leq {E}_{Up} + \qquad ( Eq . {6}^{′} )$$

$${{\sum }_{n = 1}^{N} \frac{\partial {f}_{p} ( {z}_{1} , {z}_{2} , … , {z}_{N} )}{\partial {z}_{n}} \vert}_{{z}_{1} = {z}_{1 i} , {z}_{2} = {z}_{2 i} , {…z}_{N} = {z}_{Ni}} {z}_{ni} -$$

$${f}_{p} ( {z}_{1 i} , {z}_{2 i} , … , {z}_{Ni} )$$

$$and$$

$${- {Σ}_{n = 1}^{N} \frac{\partial {f}_{p} ( {z}_{1} , {z}_{2} , … , {z}_{N} )}{\partial {z}_{n}} \vert}_{{z}_{1} = {z}_{1 i} , {z}_{2} = {z}_{2 i} , {…z}_{N} = {z}_{Ni}} {z}_{n} \leq - {E}_{Up} - \qquad ( Eq . {6}^{″} )$$

$${{Σ}_{n = 1}^{N} \frac{\partial {f}_{p} ( {z}_{1} , {z}_{2} , … , {z}_{N} )}{\partial {z}_{n}} \vert}_{{z}_{1} = {z}_{1 i} , {z}_{2} = {z}_{2 i} , {…z}_{N} = {z}_{Ni}} {z}_{ni} +$$

$${f}_{p} ( {z}_{1 i} , {z}_{2 i} , … , {z}_{Ni} )$$

Since Eq. 3 is generally valid only in the vicinity of (z₁, z₂, . . . , z_{N}), in case the desired constraints E_{Lp}≤fₚ(z₁, z₂, . . . , z_{N})≤EUₚ cannot be achieved in such vicinity, which can be determined by any conflict among the inequalities, the constants ELₚ and EUₚ can be relaxed until the constraints are achievable. This optimization process minimizes the worst defect size in the vicinity of (z₁, z₂, . . . , z_{N}), i. Then each step reduces the worst defect size gradually, and each step is executed iteratively until certain terminating conditions are met. This will lead to optimal reduction of the worst defect size.

Another way to minimize the worst defect is to adjust the weight wₚ in each iteration. For example, after the i-th iteration, if the r-th evaluation point is the worst defect, wᵣ can be increased in the (i+1)-th iteration so that the reduction of that evaluation point's defect size is given higher priority.

In addition, the cost functions in Eq. 4 and Eq. 5 can be modified by introducing a Lagrange multiplier to achieve compromise between the optimization on RMS of the defect size and the optimization on the worst defect size, i.e.,

$$CF ( {z}_{1} , {z}_{2} , … , {z}_{N} ) = ( 1 - λ ) {Σ}_{p = 1}^{P} {w}_{p} {f}_{p}^{2} ( {z}_{1} , {z}_{2} , … , {z}_{N} ) + \qquad ( Eq . {6}^{′′′} )$$

$$λ {max}_{1 \leq p \leq P} \frac{{f}_{p} ( {z}_{1} , {z}_{2} , … , {z}_{N} )}{{CL}_{p}}$$

where λ is a preset constant that specifies the trade-off between the optimization on RMS of the defect size and the optimization on the worst defect size. In particular, if λ=0, then this becomes Eq. 4 and the RMS of the defect size is only minimized; while if λ=1, then this becomes Eq. 5 and the worst defect size is only minimized; if 0<λ<1, then both are taken into consideration in the optimization. Such optimization can be solved using multiple methods. For example, the weighting in each iteration may be adjusted, similar to the one described previously. Alternatively, similar to minimizing the worst defect size from inequalities, the inequalities of Eq. 6′ and 6″ can be viewed as constraints of the design variables during solution of the quadratic programming problem. Then, the bounds on the worst defect size can be relaxed incrementally or increase the weight for the worst defect size incrementally, compute the cost function value for every achievable worst defect size, and choose the design variable values that minimize the total cost function as the initial point for the next step. By doing this iteratively, the minimization of this new cost function can be achieved.

Optimizing a lithographic projection apparatus can expand the process window. A larger process window provides more flexibility in process design and chip design. The process window can be defined as, for example, a set of focus, dose, aberration, laser bandwidth (e.g., E95 or (λ min to λ max) and fare specific to intensity values for which the resist image is within a certain limit of the design target of the resist image. Note that all the methods discussed here may also be extended to a generalized process window definition that can be established by different or additional base parameters than exposure dose and defocus. These may include, but are not limited to, optical settings such as NA, sigma, aberration, polarization, or an optical constant of the resist layer. For example, as described earlier, if the process window (PW) also comprises different patterning device pattern bias (mask bias), then the optimization includes the minimization of Mask Error Enhancement Factor (MEEF), which is defined as the ratio between the substrate edge placement error (EPE) and the induced patterning device pattern edge bias. The process window defined on focus and dose values only serve as an example in this disclosure.

A method of maximizing a process window using, for example, dose and focus as its parameters, according to an embodiment, is described below. In a first step, starting from a known condition (f₀, ε₀) in the process window, wherein f₀ is a nominal focus and ε₀ is a nominal dose, minimizing one of the cost functions below in the vicinity (f₀±Δf, ε₀±ε):

$$CF ( {z}_{1} , {z}_{2} , … , {z}_{N} , {f}_{0} , {ε}_{0} ) = {max}_{( f , ε ) = ( {f}_{0} \pm Δ f , {ε}_{0} \pm ε )} {max}_{p} \vert {f}_{p} ( {z}_{1} , {z}_{2} , … , {z}_{N} , f , ε ) \vert \qquad ( Eq . 7 )$$

$$or$$

$$CF ( {z}_{1} , {z}_{2} , … , {z}_{N} , {f}_{0} , {ε}_{0} ) = {Σ}_{( f , ε ) = ( {f}_{0} \pm Δ f , {ε}_{0} \pm ε )} {Σ}_{p} {w}_{p} {f}_{p}^{2} ( {z}_{1} , {z}_{2} , … , {z}_{N} , f , ε ) \qquad ( Eq . {7}^{′} )$$

$$or$$

$$CF ( {z}_{1} , {z}_{2} , … , {z}_{N} , {f}_{0} , {ε}_{0} ) = ( 1 - λ ) {Σ}_{( f , ε ) = ( {f}_{0} \pm Δ f , {ε}_{0} \pm ε )} {Σ}_{p} {w}_{p} {f}_{p}^{2} ( {z}_{1} , {z}_{2} , … , {z}_{N} , f , ε ) + λ {max}_{( f , ε ) = ( {f}_{0} \pm Δ f , {ε}_{0} \pm ε )} {max}_{p} \vert {f}_{p} ( {z}_{1} , {z}_{2} , … , {z}_{N} , f , ε ) \vert \qquad ( Eq . {7}^{″} )$$

If the nominal focus f₀ and nominal dose ε₀ are allowed to shift, they can be optimized jointly with the design variables (z₁, z₂, . . . , z_{N}). In the next step, (f₀±Δf, ε₀±ε) is accepted as part of the process window, if a set of values of (z₁, z₂, . . . , z_{N}, f, ε) can be found such that the cost function is within a preset limit.

If the focus and dose are not allowed to shift, the design variables (z₁, z₂, . . . , z_{N}) are optimized with the focus and dose fixed at the nominal focus f₀ and nominal dose ε₀. In an alternative embodiment, (f₀±Δf, ε₀±ε) is accepted as part of the process window, if a set of values of (z₁, z₂, . . . , z_{N}) can be found such that the cost function is within a preset limit.

The methods described earlier in this disclosure can be used to minimize the respective cost functions of Eqs. 7, 7′, or 7″. If the design variables represent one or more characteristics of the projection optics, such as the zernike coefficients, then minimizing the cost functions of Eqs. 7, 7′, or 7″ leads to process window maximization based on projection optics optimization, i.e., LO. If the design variables represent one or more characteristics of the illumination and patterning device in addition to those of the projection optics, then minimizing the cost function of Eqs. 7, 7′, or 7″ leads to process window maximizing based on SMLO, as illustrated in FIG. 10. If the design variables represented one or more characteristics of the source and patterning device, then minimizing the cost functions of Eqs. 7, 7′, or 7″ leads to process window maximization based on SMO. The cost functions of Eqs. 7, 7′, or 7″ can also include at least one fₚ(z₁, z₂, . . . , z_{N}) such as described herein, that is a function of the bandwidth.

FIG. 13 shows one specific example of how a simultaneous SMLO process can use a gradient based optimization (e.g., quasi newton, or Gauss Newton Algorithm). In step S702, starting values of one or more design variables are identified. A tuning range for each variable may also be identified. In step S704, the cost function is defined using the one or more design variables. In step S706, the cost function is expanded around the starting values for all evaluation points in the design layout. In step S708, a suitable optimization technique is applied to minimize or maximize the cost function. In optional step S710, a full-chip simulation is executed to cover all critical patterns in a full-chip design layout. A desired lithographic response metric (such as CD, EPE, or EPE and PPE) is obtained in step S714, and compared with predicted values of those quantities in step S712. In step S716, a process window is determined. Steps S718, S720, and S722 are similar to corresponding steps S514, S516 and S518, as described with respect to FIG. 12A. As mentioned before, the final output may be, for example, a wavefront aberration map in the pupil plane, optimized to produce the desired imaging performance. The final output may be, for example, an optimized illumination map and/or an optimized design layout.

FIG. 12B shows an exemplary method to optimize the cost function where the design variables (z₁, z₂, . . . , z_{N}) include design variables that may only assume discrete values.

The method starts by defining the pixel groups of the illumination and the patterning device tiles of the patterning device (step S802). Generally, a pixel group or a patterning device tile may also be referred to as a division of a lithographic process component. In one exemplary approach, the illumination is divided into 117 pixel groups, and 94 patterning device tiles are defined for the patterning device, substantially as described above, resulting in a total of 211 divisions.

In step S804, a lithographic model is selected as the basis for lithographic simulation. A lithographic simulation produces results that are used in calculations of one or more lithographic metrics, or responses. A particular lithographic metric is defined to be the performance metric that is to be optimized (step S806). In step S808, the initial (pre-optimization) conditions for the illumination and the patterning device are set up. Initial conditions include initial states for the pixel groups of the illumination and the patterning device tiles of the patterning device such that references may be made to an initial illumination shape and an initial patterning device pattern. Initial conditions may also include patterning device pattern bias (sometimes referred to as mask bias), NA, and/or focus ramp range. Although steps S802, S804, S806, and S808 are depicted as sequential steps, it will be appreciated that in other embodiments, these steps may be performed in other sequences.

In step S810, the pixel groups and patterning device tiles are ranked. Pixel groups and patterning device tiles may be interleaved in the ranking. Various ways of ranking may be employed, including: sequentially (e.g., from pixel group 1 to pixel group 117 and from patterning device tile 1 to patterning device tile 94), randomly, according to the physical locations of the pixel groups and patterning device tiles (e.g., ranking pixel groups closer to the center of the illumination higher), and/or according to how an alteration of the pixel group or patterning device tile affects the performance metric.

Once the pixel groups and patterning device tiles are ranked, the illumination and patterning device are adjusted to improve the performance metric (step S812). In step S812, each of the pixel groups and patterning device tiles are analyzed, in order of ranking, to determine whether an alteration of the pixel group or patterning device tile will result in an improved performance metric. If it is determined that the performance metric will be improved, then the pixel group or patterning device tile is accordingly altered, and the resulting improved performance metric and modified illumination shape or modified patterning device pattern form the baseline for comparison for subsequent analyses of lower-ranked pixel groups and patterning device tiles. In other words, alterations that improve the performance metric are retained. As alterations to the states of pixel groups and patterning device tiles are made and retained, the initial illumination shape and initial patterning device pattern changes accordingly, so that a modified illumination shape and a modified patterning device pattern result from the optimization process in step S812.

In other approaches, patterning device polygon shape adjustments and pairwise polling of pixel groups and/or patterning device tiles are also performed within the optimization process of S812.

In an embodiment, the interleaved simultaneous optimization procedure may include altering a pixel group of the illumination and if an improvement of the performance metric is found, the dose or intensity is stepped up and/or down to look for further improvement. In a further embodiment, the stepping up and/or down of the dose or intensity may be replaced by a bias change of the patterning device pattern to look for further improvement in the simultaneous optimization procedure.

In step S814, a determination is made as to whether the performance metric has converged. The performance metric may be considered to have converged, for example, if little or no improvement to the performance metric has been witnessed in the last several iterations of steps S810 and S812. If the performance metric has not converged, then the steps of S810 and S812 are repeated in the next iteration, where the modified illumination shape and modified patterning device from the current iteration are used as the initial illumination shape and initial patterning device for the next iteration (step S816).

The optimization methods described above may be used to increase the throughput of the lithographic projection apparatus. For example, the cost function may include a fₚ(z₁, z₂, . . . , z_{N}) that is a function of the exposure time. In an embodiment, optimization of such a cost function is constrained or influenced by a measure of the bandwidth or other metric.

FIG. 14 is a block diagram that illustrates a computer system 100 which can assist in implementing the optimization methods and flows disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the optimization process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 may also include a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

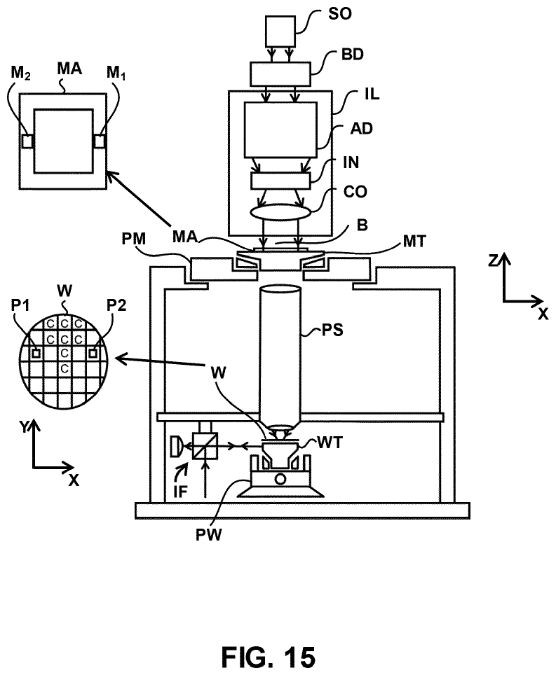

FIG. 15 schematically depicts an exemplary lithographic projection apparatus whose illumination could be optimized utilizing the methods described herein. The apparatus comprises:
an illumination system IL, to condition a beam B of radiation. In this particular case, the illumination system also comprises a radiation source SO;
a first object table (e.g., patterning device table) MT provided with a patterning device holder to hold a patterning device MA (e.g., a reticle), and connected to a first positioner to accurately position the patterning device with respect to item PS;
a second object table (substrate table) WT provided with a substrate holder to hold a substrate W (e.g., a resist-coated silicon wafer), and connected to a second positioner to accurately position the substrate with respect to item PS;
a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

It should be noted with regard to FIG. 15 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

The beam PB subsequently intercepts the patterning device MA, which is held on a patterning device table MT. Having traversed the patterning device MA, the beam B passes through the lens PL, which focuses the beam B onto a target portion C of the substrate W. With the aid of the second positioning means (and interferometric measuring means IF), the substrate table WT can be moved accurately, e.g., so as to position different target portions C in the path of the beam PB. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted in FIG. 15. However, in the case of a stepper (as opposed to a step-and-scan tool) the patterning device table MT may just be connected to a short stroke actuator, or may be fixed.

The depicted tool can be used in two different modes:
In step mode, the patterning device table MT is kept essentially stationary, and an entire patterning device image is projected in one go (i.e., a single “flash”) onto a target portion C. The substrate table WT is then shifted in the x and/or y directions so that a different target portion C can be irradiated by the beam PB;
In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

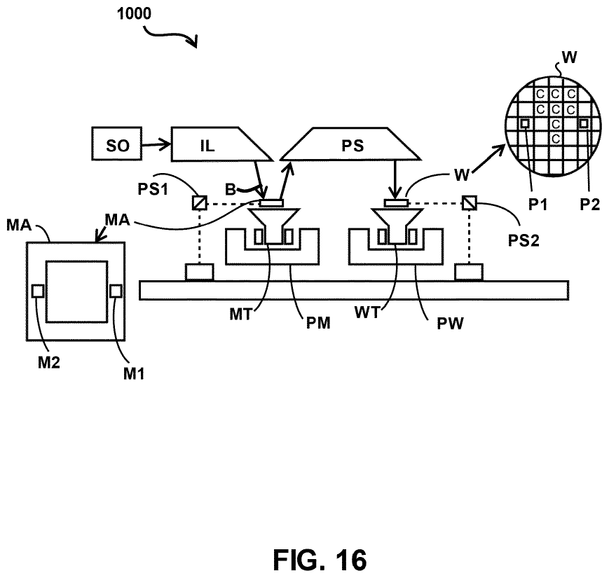

FIG. 16 schematically depicts another exemplary lithographic projection apparatus 1000 whose illumination could be optimized utilizing the methods described herein.

The lithographic projection apparatus 1000 comprises:
a source collector module SO
an illumination system (illuminator) IL configured to condition a radiation beam B (e.g., EUV radiation).
a support structure (e.g., a patterning device table) MT constructed to support a patterning device (e.g., a mask or a reticle) MA and connected to a first positioner PM configured to accurately position the patterning device;
a substrate table (e.g., a wafer table) WT constructed to hold a substrate (e.g., a resist coated wafer) W and connected to a second positioner PW configured to accurately position the substrate; and
a projection system (e.g., a reflective projection system) PS configured to project a pattern imparted to the radiation beam B by patterning device MA onto a target portion C (e.g., comprising one or more dies) of the substrate W.

As here depicted, the apparatus 1000 is of a reflective type (e.g., employing a reflective patterning device). It is to be noted that because most materials are absorptive within the EUV wavelength range, the patterning device may have multilayer reflectors comprising, for example, a multi-stack of Molybdenum and Silicon. In one example, the multi-stack reflector has a 40 layer pairs of Molybdenum and Silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Referring to FIG. 16, the illuminator IL receives an extreme ultra-violet radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. The source collector module SO may be part of an EUV radiation system including a laser, not shown in FIG. 16, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., patterning device table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using patterning device alignment marks M1, M2 and substrate alignment marks P1, P2.

The depicted apparatus 1000 could be used in at least one of the following modes:

1. In step mode, the support structure (e.g., patterning device table) MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed.

2. In scan mode, the support structure (e.g., patterning device table) MT and the substrate table WT are scanned synchronously while a pattern imparted to the radiation beam is projected onto a target portion C (i.e., a single dynamic exposure). The velocity and direction of the substrate table WT relative to the support structure (e.g., patterning device table) MT may be determined by the (de-)magnification and image reversal characteristics of the projection system PS.

3. In another mode, the support structure (e.g., patterning device table) MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

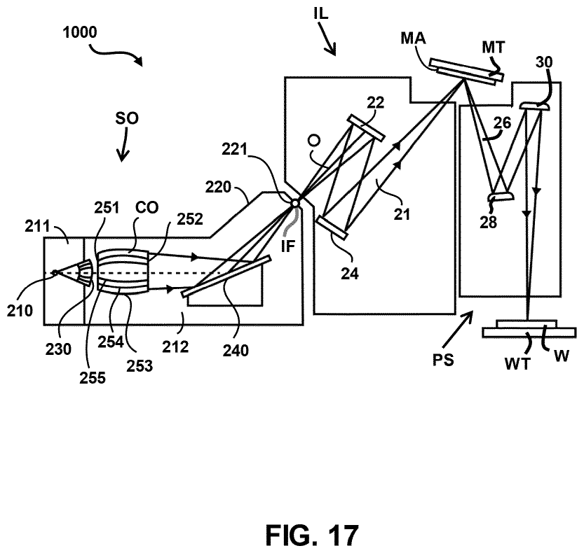

FIG. 17 shows the apparatus 1000 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused on a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 17.

Collector optic CO, as illustrated in FIG. 17, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

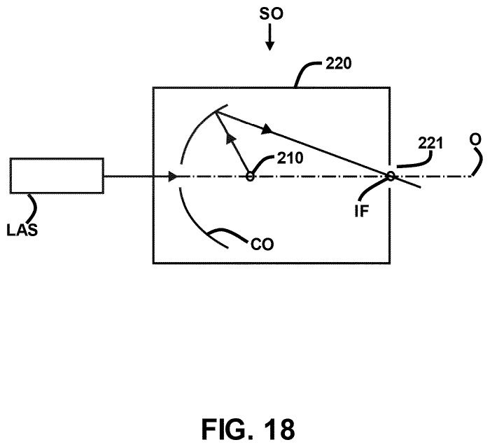

Alternatively, the source collector module SO may be part of an LPP radiation system as shown in FIG. 18. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features and may be especially useful with emerging imaging technologies capable of producing increasingly shorter wavelengths. Emerging technologies already in use include EUV (extreme ultra-violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

Embodiments of the present disclosure can be further described by the following clauses.

1. A non-transitory computer-readable medium configured for generating rounded contours for lithographic mask patterns, the medium comprising instructions stored therein that, when executed by one or more processors, cause operations comprising:
converting a contour representation of a mask pattern to (i) a first set of contour point locations in a first dimension and (ii) a second set of contour point locations in a second dimension different from the first dimension;
determining a signal function based on the first set and the second set of contour point locations, the signal function indicative of different segments of the contour representation;
updating (i) the first set of contour point locations based on the first filter function and the signal function, and (ii) the second set of contour point locations based on the second filter function and the signal function; and
generating, based on the updated first set of contour point locations and the updated second set of contour point locations, a rounded contour of the contour representation of the mask pattern.
   2. The medium of clause 1, wherein updating comprises:
generating (i) a first set of weights corresponding to the first set of contour point locations by applying a first filter function to the signal function, and (ii) a second set of weights corresponding to the second set of contour point locations by applying a second filter to the signal function; and
updating (i) the first set of contour point locations based on the first filter function and the first set of weights, and (ii) the second set of contour point locations based on the second filter function and the second set of weights.
   3. The medium of any of clauses 1-2, wherein converting the contour representation comprises:
sampling a plurality of points at a specific interval on the contour representation;
converting the plurality of points to the first set of contour point locations in the first dimension;
   and
converting the plurality of points to the second set of contour point locations in the second dimension.
   4. The medium of clause 3, wherein converting the contour representation further comprises:
determining a first gradient based on the first set of contour point locations in the first dimension;
   and
determining a second gradient based on the second set of contour point locations in the second dimension.
   5. The medium of any of clauses 1-4, wherein determining the signal function comprises:
computing a product of a first difference between two consecutive points in the first set of contour point locations and a second difference between two consecutive points in the second set of contour point locations.
   6. The medium of clause 5, wherein determining the signal function comprises:
determining a first function having values greater than zero, the first function characterizing a first type of corners in the contour representation; and
determining a second function having values lower than zero, the second function characterizing a second type of corners in the contour representation.
   7. The medium of clause 6, wherein the first function indicates an inner corner of the contour representation, and a second function indicates an outer corner within the contour representation, the inner corner or the outer corner characterizing a corner orientation within the contour representation.
   8. The medium of clause 7, wherein generating the first set of weights and the second set of weights comprises:
generating, in the first dimension, a subset of weights corresponding to the inner corner; and another subset of weights corresponding to the outer corner; and
generating, in the second dimension, a subset of weights corresponding to the inner corner; and another subset of weights corresponding to the outer corner.
   9. The medium of any of clauses 2-8, wherein updating the first set of contour point locations and the second set of contour point locations comprises:
computing, in the first dimension, a third set of contour points as a function of the first set of contour point locations, the first filter function, and the first set of weights; and
computing, in the second dimension, a fourth set of contour points as a function of the second set of contour point locations, the second filter function, and the second set of weights.
   10. The medium of clause 9, wherein computing in the first dimension comprises:
determining at each point of the first set of contour points whether a sum of weights of the first set of weights at that particular point is equal to zero;
responsive to the sum not being zero, transforming a particular point of the first set of contour point locations by applying the first filter function and taking a weighted average of the filtered point using the first set of weights; and
responsive to the sum being zero, not transforming the particular of the first set of contour point locations.
   11. The medium of clause 9, wherein computing in the second dimension comprises:
determining at each point of the second set of contour points whether a sum of weights of the second set of weights at that particular point is equal to zero;
responsive to the sum not being zero, transforming the particular point of the second set of contour point locations by applying the second filter function and taking a weighted average of the filtered point using the second set of weights; and
responsive to the sum being zero, not transforming the particular of the second set of contour point locations.
   12. The medium of any of clauses 1-11, wherein generating the rounded contour comprises:
combining the converted first set and the converted second set of contour point locations to generate a set of 2D contour points; and
joining the set of 2D contour points to generate the rounded contour of the contour representation.
   13. The medium of any of clauses 1-12, wherein joining the contour points comprises:
joining adjacent points of the set of 2D contour points by a linear function, a polynomial function or a combination of linear and polynomial functions, to generate an enclosed contour.
   14. The medium of any of clauses 1-13, further comprising:
generating a mask design based on the rounded contour of the contour representation.
   15. The medium of clause 14, wherein the generating the mask design comprises:
(a) accessing a design layout comprising a plurality of contour representation;
(b) generating rounded contours for each of the plurality of the contour representations by converting each contour representation into 1D representations, applying filters to each of the 1D representations, and combining the filtered 1D contour representations;
(c) simulating a patterning process using the rounded contours to generate simulated contours associated with a semiconductor chip;
(d) obtaining printed contours of a patterned substrate patterned using a mask associated with the design layout;
(e) determining whether the simulated contours and the printed contours are within a matching threshold; and
(f) responsive to the simulated contours not matching the printed contours, adjusting parameters or contents of the first filter function, the second filter function, or both the filter functions, and repeating steps (a)-(f).
   16. The medium of clause 14, further comprising:
(a) accessing a design layout comprising a plurality of contour representation;
(b) generating rounded contours for each of the plurality of the contour representations by converting each contour representation into 1D representations, applying filters to each of the 1D representations, and combining the filtered 1D contour representations;
(c) simulating, using the rounded contours, an optimal proximity correction process to generate simulated contours associated with a substrate;
(d) determining whether the simulated contours satisfy design specifications; and
(e) responsive to the simulated contours not satisfying the design specification, adjusting the design layout, and repeating steps (a)-(e).
   17. The medium of any of clauses 1-16, further comprising:
(a) accessing a design layout comprising a plurality of contour representation;
(b) generating rounded contours for each of the plurality of the contour representations by converting each contour representation into 1D representations, applying filters to each of the 1D representations, and combining the filtered 1D contour representations;
(c) simulating, using the rounded contours, an optimal proximity correction process to generate mask patterns;
(d) determining whether the mask patterns satisfy mask rule check (MRC) conditions; and
(e) responsive to the mask patterns not satisfying the MRC, adjusting the design layout, and repeating steps (a)-(e).
   18. The medium of any of clauses 1-17, wherein each of the first filter function and the second filter function comprises a Gaussian filter, and/or a low pass filter.
   19. A non-transitory computer-readable medium configured for determining rounded contours for lithographic masks, the medium comprising instructions stored therein that, when executed by one or more processors, cause operations comprising:
converting a contour representation of a mask pattern to a one dimensional (1D) representation using a unit directional vector and constraining the 1D representation to satisfy a constrain that is proportional to the unit directional vector;
determining (i) a first function of the 1D representation by taking a gradient of the 1D representation with respect to a first dimension; and (ii) a second function of the 1D representation by taking another gradient of the 1D representation with respect to a second dimension, the first and the second functions satisfying the constrain;
generating (i) a first filtered function by convoluting the first function with a first filter, and (ii) a second filtered function by convoluting the second function with a second filter; and
generating a rounded contour for the mask pattern by combing the first filtered function and the second filtered function of the contour representation.
   20. The medium of clause 19, further comprises:
distinguishing a first type of corners in the contour representation and a second type of corners in the contour representation; and
defining the first filter function and/or the second filter function to comprise a filter function for the first type of corners and another filter function for the second type of corners.
   21. The medium of clause 20, distinguishing the corners comprises:
computing a signum function of the first function and the second function of the 1D representation, where a positive value of the signum function indicates the first type of corner, and a negative value of the signum function indicates the second type of corner.
   22. The medium of clause 20, wherein generating of the rounded corners comprises:
generating the first filtered function using the filter function for the first type of corners and the other filter function for the second type of corners.
   23. The medium of any of clauses 19-22, wherein converting the contour representation comprises:
selecting a starting point on the contour representation; and
transforming an enclosed shape of the contour representation into a straight line by unfolding the contour representing from the starting point.
   24. The medium of any of clauses 19-23, wherein determining the first function of the 1D representation comprises:
generating a first step function in the first dimension based on a length of segments of the contour representation in the first dimension and the second dimension, and a direction of traverse along the contour representation.
   25. The medium of any of clauses 19-24, wherein determining the second function of the 1D representation comprises:
generating a second step function in the second dimension based on a length of segments of the contour representation in the first dimension and the second dimension, and a direction of traverse along the contour representation.
   26. The medium of any of clauses 19-25, wherein determining the first function of the 1D representation comprises:
computing a cosine function along the contour representation using an angle between edges in the contour representation.
   27. The medium of any of clauses 19-26, wherein determining the second function of the 1D representation comprises:
computing a sine function along the contour representation using an angle between edges in the contour representation.
   28. The medium of any of clauses 19-27, wherein generating the first filtered function comprises:
convoluting the first function with the first filter causing at least a portion of a shape represented by the first function to be rounded.
   29. The medium of any of clauses 19-28, wherein generating the first filtered function and the second filtered function comprises:
constraining the generation operation to satisfy a first condition that absolute value of the unit vector convoluted with the first and second filter functions is unity, which is expressed as |\vec{u}*f|=1, wherein * indicates a convolution operation, \vec{u} is the unit vector comprising the 1D representations in the first dimension and the second dimension, and f comprises the first filter function and the second filter function.
   30. The medium of clause 29, wherein generating the first filtered function and the second filtered function comprises:
constraining the generation operation to satisfy a second condition that a steady state response to a unit step function is unity, which is expressed as ∫\vec{u}*f ds=0, wherein * indicates a convolution operation, \vec{u} is the unit vector comprising the 1D representations in the first dimension and the second dimension, and f comprises the first filter function and the second filter function.
   31. The medium of any of clauses 19-30, wherein generating the second filtered function comprises:
convoluting the second function with the second filter causing at least a portion of a shape represented by the second function to be rounded.
   32. The medium of any of clauses 19-31, wherein generating the rounded contour comprises:
integrating the first filtered function along a length of the 1D representation;
integrating the second filtered function along a length of the 1D representation; and
combining the integrated functions to generate the rounded contour.
   33. The medium of any of clauses 19-32, wherein the constrain is a constrain indicative of an enclosed contour, and/or unity constrain.
   34. The medium of any of clauses 19-33, further comprises:
determining a center of the rounded contour, and a center of the contour representation; and
aligning the centers of the rounded contour and the contour representation.
   35. The medium of any of clauses 19-34, further comprising:
generating a mask design based on the rounded contour of the contour representation.
   36. The medium of clause 35, generating the mask design comprises:
(a) accessing a design layout comprising a plurality of contour representation;
(b) generating rounded contours for each of the plurality of the contour representations by converting each contour representation into 1D representations, applying filters to each of the 1D representations, and combining the filtered 1D contour representations;
(c) simulating a patterning process using the rounded contours to generate simulated contours associated with a semiconductor chip;
(d) obtaining printed contours of a patterned substrate patterned using a mask associated with the design layout;
(e) determining whether the simulated contours and the printed contours are within a matching threshold; and
(f) responsive to the simulated contours not matching the printed contours, adjusting parameters or contents of the one or more 1D filters and repeating steps (a)-(f).
   37. The medium of clause 35, further comprising:
(a) accessing a design layout comprising a plurality of contour representation;
(b) generating rounded contours for each of the plurality of the contour representations by converting each contour representation into 1D representations, applying filters to each of the 1D representations, and combining the filtered 1D contour representations;
(c) simulating, using the rounded contours, an optimal proximity correction process to generate simulated contours associated with a substrate;
(d) determining whether the simulated contours satisfy design specifications; and
(e) responsive to the simulated contours not satisfying the design specification, adjusting the design layout, and repeating steps (a)-(e).
   38. The medium of any of clauses 19-37, further comprising:
(a) accessing a design layout comprising a plurality of contour representation;
(b) generating rounded contours for each of the plurality of the contour representations by converting each contour representation into 1D representations, applying filters to each of the 1D representations, and combining the filtered 1D contour representations;
(c) simulating, using the rounded contours, an optimal proximity correction process to generate mask patterns;
(d) determining whether the mask patterns satisfy mask rule check (MRC) conditions; and
(e) responsive to the mask patterns not satisfying the MRC, adjusting the design layout, and repeating steps (a)-(e).
   39. A method for generating rounded contours for lithographic mask patterns comprising:
converting a contour representation of a mask pattern to (i) a first set of contour point locations in a first dimension and (ii) a second set of contour point locations in a second dimension different from the first dimension;
determining a signal function based on the first set and the second set of contour point locations, the signal function indicative of different segments of the contour representation;
updating (i) the first set of contour point locations based on the first filter function and the signal function, and (ii) the second set of contour point locations based on the second filter function and the signal function; and
generating, based on the updated first set of contour point locations and the updated second set of contour point locations, a rounded contour of the contour representation of the mask pattern.
   40. The method of clause 39, wherein updating comprises:
generating (i) a first set of weights corresponding to the first set of contour point locations by applying a first filter function to the signal function, and (ii) a second set of weights corresponding to the second set of contour point locations by applying a second filter to the signal function; and
updating (i) the first set of contour point locations based on the first filter function and the first set of weights, and (ii) the second set of contour point locations based on the second filter function and the second set of weights.
   41. The method of any of clauses 39-40, wherein converting the contour representation comprises:
sampling a plurality of points at a specific interval on the contour representation;
converting the plurality of points to the first set of contour point locations in the first dimension;
   and
converting the plurality of points to the second set of contour point locations in the second dimension.
   42. The method of clause 41, wherein converting the contour representation further comprises:
determining a first gradient based on the first set of contour point locations in the first dimension;
   and
determining a second gradient based on the second set of contour point locations in the second dimension.
   43. The method of any of clauses 39-42, wherein determining the signal function comprises:
computing a product of a first difference between two consecutive points in the first set of contour point locations and a second difference between two consecutive points in the second set of contour point locations.
   44. The method of clause 43, wherein determining the signal function comprises:
determining a first function having values greater than zero, the first function characterizing a first type of corners in the contour representation; and
determining a second function having values lower than zero, the second function characterizing a second type of corners in the contour representation.
   45. The method of clause 44, wherein the first function indicates an inner corner of the contour representation, and a second function indicates an outer corner within the contour representation, the inner corner or the outer corner characterizing a corner orientation within the contour representation.
   46. The method of clause 45, wherein generating the first set of weights and the second set of weights comprises:
generating, in the first dimension, a subset of weights corresponding to the inner corner; and another subset of weights corresponding to the outer corner; and
generating, in the second dimension, a subset of weights corresponding to the inner corner; and another subset of weights corresponding to the outer corner.
   47. The method of any of clauses 40-46, wherein updating the first set of contour point locations and the second set of contour point locations comprises:
computing, in the first dimension, a third set of contour points as a function of the first set of contour point locations, the first filter function, and the first set of weights; and
computing, in the second dimension, a fourth set of contour points as a function of the second set of contour point locations, the second filter function, and the second set of weights.
   48. The method of clause 47, wherein computing in the first dimension comprises:
determining at each point of the first set of contour points whether a sum of weights of the first set of weights at that particular point is equal to zero;
responsive to the sum not being zero, transforming a particular point of the first set of contour point locations by applying the first filter function and taking a weighted average of the filtered point using the first set of weights; and
responsive to the sum being zero, not transforming the particular of the first set of contour point locations.
   49. The method of clause 48, wherein computing in the second dimension comprises:
determining at each point of the second set of contour points whether a sum of weights of the second set of weights at that particular point is equal to zero;
responsive to the sum not being zero, transforming the particular point of the second set of contour point locations by applying the second filter function and taking a weighted average of the filtered point using the second set of weights; and
responsive to the sum being zero, not transforming the particular of the second set of contour point locations.
   50. The method of any of clauses 39-49, wherein generating the rounded contour comprises:
combining the converted first set and the converted second set of contour point locations to generate a set of 2D contour points; and
joining the set of 2D contour points to generate the rounded contour of the contour representation.
   51. The method of any of clauses 39-50, wherein joining the contour points comprises:
joining adjacent points of the set of 2D contour points by a linear function, a polynomial function or a combination of linear and polynomial functions, to generate an enclosed contour.
   52. The method of any of clauses 39-51, further comprising:
generating a mask design based on the rounded contour of the contour representation.
   53. The method of clause 52, wherein the generating the mask design comprises:
(a) accessing a design layout comprising a plurality of contour representation;
(b) generating rounded contours for each of the plurality of the contour representations by converting each contour representation into 1D representations, applying filters to each of the 1D representations, and combining the filtered 1D contour representations;
(c) simulating a patterning process using the rounded contours to generate simulated contours associated with a semiconductor chip;
(d) obtaining printed contours of a patterned substrate patterned using a mask associated with the design layout;
(e) determining whether the simulated contours and the printed contours are within a matching threshold; and
(f) responsive to the simulated contours not matching the printed contours, adjusting parameters or contents of the first filter function, the second filter function, or both the filter functions, and repeating steps (a)-(f).
   54. The method of clause 52, further comprising:
(a) accessing a design layout comprising a plurality of contour representation;
(b) generating rounded contours for each of the plurality of the contour representations by converting each contour representation into 1D representations, applying filters to each of the 1D representations, and combining the filtered 1D contour representations;
(c) simulating, using the rounded contours, an optimal proximity correction process to generate simulated contours associated with a substrate;
(d) determining whether the simulated contours satisfy design specifications; and
(e) responsive to the simulated contours not satisfying the design specification, adjusting the design layout, and repeating steps (a)-(e).
   55. The method of any of clauses 39-54, further comprising:
(a) accessing a design layout comprising a plurality of contour representation;
(b) generating rounded contours for each of the plurality of the contour representations by converting each contour representation into 1D representations, applying filters to each of the 1D representations, and combining the filtered 1D contour representations;
(c) simulating, using the rounded contours, an optimal proximity correction process to generate mask patterns;
(d) determining whether the mask patterns satisfy mask rule check (MRC) conditions; and
(e) responsive to the mask patterns not satisfying the MRC, adjusting the design layout, and repeating steps (a)-(e).
   56. The method of any of clauses 39-55, wherein each of the first filter function and the second filter function comprises a Gaussian filter, and/or a low pass filter.
   57. A method for determining rounded contours for lithographic masks comprising:
converting a contour representation of a mask pattern to a one dimensional (1D) representation using a unit directional vector and constraining the 1D representation to satisfy a constrain that is proportional to the unit directional vector;
determining (i) a first function of the 1D representation by taking a gradient of the 1D representation with respect to a first dimension; and (ii) a second function of the 1D representation by taking another gradient of the 1D representation with respect to a second dimension, the first and the second functions satisfying the constrain;
generating (i) a first filtered function by applying a first filter to the first function, and (ii) a second filtered function by applying a second filter to the second function; and
generating a rounded contour for the mask pattern by combing the first filtered function and the second filtered function of the contour representation.
   58. The method of clause 57, further comprises:
distinguishing a first type of corners in the contour representation and a second type of corners in the contour representation; and
defining the first filter function and/or the second filter function to comprise a filter function for the first type of corners and another filter function for the second type of corners.
   59. The method of clause 58, distinguishing the corners comprises:
computing a signum function of the first function and the second function of the 1D representation, where a positive value of the signum function indicates the first type of corner, and a negative value of the signum function indicates the second type of corner.
   60. The method of clause 58, wherein generating of the rounded corners comprises:
generating the first filtered function using the filter function for the first type of corners and the other filter function for the second type of corners.
   61. The method of any of clauses 57-60, wherein converting the contour representation comprises:
selecting a starting point on the contour representation; and
transforming an enclosed shape of the contour representation into a straight line by unfolding the contour representing from the starting point.
   62. The method of any of clauses 57-61, wherein determining the first function of the 1D representation comprises:
generating a first step function in the first dimension based on a length of segments of the contour representation in the first dimension and the second dimension, and a direction of traverse along the contour representation.
   63. The method of any of clauses 57-62, wherein determining the second function of the 1D representation comprises:
generating a second step function in the second dimension based on a length of segments of the contour representation in the first dimension and the second dimension, and a direction of traverse along the contour representation.
   64. The method of any of clauses 57-63, wherein determining the first function of the 1D representation comprises:
computing a cosine function along the contour representation using an angle between edges in the contour representation.
   65. The method of any of clauses 57-64, wherein determining the second function of the 1D representation comprises:
computing a sine function along the contour representation using an angle between edges in the contour representation.
   66. The method of any of clauses 57-65, wherein generating the first filtered function comprises:
convoluting the first function with the first filter causing at least a portion of a shape represented by the first function to be rounded.
   67. The method of any of clauses 57-66, wherein generating the first filtered function and the second filtered function comprises:
constraining the generation operation to satisfy a first condition that absolute value of the unit vector convoluted with the first and second filter functions is unity, which is expressed as |\vec{u}*f|=1, wherein * indicates a convolution operation, u is the unit vector comprising the 1D representations in the first dimension and the second dimension, and f comprises the first filter function and the second filter function.
   68. The method of clause 67, wherein generating the first filtered function and the second filtered function comprises:
constraining the generation operation to satisfy a second condition that a steady state response to a unit step function is unity, which is expressed as ∫\vec{u}*f ds=0, wherein * indicates a convolution operation, \vec{u} is the unit vector comprising the 1D representations in the first dimension and the second dimension, and f comprises the first filter function and the second filter function.
   69. The method of any of clauses 57-68, wherein generating the second filtered function comprises:
convoluting the second function with the second filter causing at least a portion of a shape represented by the second function to be rounded.
   70. The method of any of clauses 57-69, wherein generating the rounded contour comprises:
integrating the first filtered function along a length of the 1D representation;
integrating the second filtered function along a length of the 1D representation; and
combining the integrated functions to generate the rounded contour.
   71. The method of any of clauses 57-70, wherein the constrain is a constrain indicative of an enclosed contour, and/or unity constrain.
   72. The method of any of clauses 57-71, further comprises:
determining a center of the rounded contour, and a center of the contour representation; and
aligning the centers of the rounded contour and the contour representation.
   73. The method of any of clauses 57-72, further comprising:
generating a mask design based on the rounded contour of the contour representation.
   74. The method of clause 73, generating the mask design comprises:
(a) accessing a design layout comprising a plurality of contour representation;
(b) generating rounded contours for each of the plurality of the contour representations by converting each contour representation into 1D representations, applying filters to each of the 1D representations, and combining the filtered 1D contour representations;
(c) simulating a patterning process using the rounded contours to generate simulated contours associated with a semiconductor chip;
(d) obtaining printed contours of a patterned substrate patterned using a mask associated with the design layout;
(e) determining whether the simulated contours and the printed contours are within a matching threshold; and
(f) responsive to the simulated contours not matching the printed contours, adjusting parameters or contents of the one or more 1D filters and repeating steps (a)-(f).
   75. The method of clause 73, further comprising:
(a) accessing a design layout comprising a plurality of contour representation;
(b) generating rounded contours for each of the plurality of the contour representations by converting each contour representation into 1D representations, applying filters to each of the 1D representations, and combining the filtered 1D contour representations;
(c) simulating, using the rounded contours, an optimal proximity correction process to generate simulated contours associated with a substrate;
(d) determining whether the simulated contours satisfy design specifications; and
(e) responsive to the simulated contours not satisfying the design specification, adjusting the design layout, and repeating steps (a)-(e).
   76. The method of any of clauses 57-75, further comprising:
(a) accessing a design layout comprising a plurality of contour representation;
(b) generating rounded contours for each of the plurality of the contour representations by converting each contour representation into 1D representations, applying filters to each of the 1D representations, and combining the filtered 1D contour representations;
(c) simulating, using the rounded contours, an optimal proximity correction process to generate mask patterns;
(d) determining whether the mask patterns satisfy mask rule check (MRC) conditions; and
(e) responsive to the mask patterns not satisfying the MRC, adjusting the design layout, and repeating steps (a)-(e).

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The descriptions above are intended to be illustrative, not limiting. Thus, it will be apparent to one skilled in the art that modifications may be made as described without departing from the scope of the claims set out below.

1.-15. (canceled)

16. A non-transitory computer-readable medium comprising instructions stored therein, the instructions, when executed by one or more processors, configured to cause the one or more processors to at least:
convert a contour representation of a mask pattern to (i) a first set of contour point locations in a first dimension and (ii) a second set of contour point locations in a second dimension different from the first dimension;
determine a signal function based on the first and second sets of contour point locations, the signal function indicative of different segments of the contour representation;
update (i) the first set of contour point locations based on a first filter function and the signal function, and (ii) the second set of contour point locations based on a second filter function and the signal function; and
generate, based on the updated first and second sets of contour point locations, a rounded contour of the contour representation of the mask pattern.

17. The medium of claim 16, wherein the instructions configured to cause the one or more processors to update (i) and (ii) are further configured to cause the one or more processors to:
generate (iii) a first set of weights corresponding to the first set of contour point locations by application of the first filter function to the signal function, and (iv) a second set of weights corresponding to the second set of contour point locations by application of the second filter function to the signal function; and
update (v) the first set of contour point locations based on the first set of weights, and (vi) the second set of contour point locations based on the second set of weights.

18. The medium of claim 16, wherein the instructions configured to cause the one or more processors to convert the contour representation are further configured to cause the one or more processors to:
sample a plurality of points at a specific interval on the contour representation;
convert the plurality of points to the first set of contour point locations in the first dimension; and
convert the plurality of points to the second set of contour point locations in the second dimension.

19. The medium of claim 18, wherein the instructions configured to cause the one or more processors to convert the contour representation are further configured to cause the one or more processors to:
determine a first gradient based on the first set of contour point locations in the first dimension; and
determine a second gradient based on the second set of contour point locations in the second dimension.

20. The medium of claim 16, wherein the instructions configured to cause the one or more processors to determine the signal function are further configured to cause the one or more processors to compute a product of a first difference between two consecutive points in the first set of contour point locations and a second difference between two consecutive points in the second set of contour point locations.

21. The medium of claim 16, wherein the instructions configured to cause the one or more processors to determine the signal function are further configured to cause the one or more processors to:
determine a first function having values in a first range of values, the first function characterizing a first type of corners in the contour representation; and
determining a second function having values in a second range of values different than the first range of values, the second function characterizing a second type of corners in the contour representation.

22. The medium of claim 21, wherein the first function indicates an inner corner of the contour representation, and the second function indicates an outer corner within the contour representation, the inner corner or the outer corner characterizing a corner orientation within the contour representation.

23. The medium of claim 22, wherein the instructions are further configured to cause the one or more processors to:
generate, in the first dimension, a subset of weights corresponding to the inner corner and another subset of weights corresponding to the outer corner; and
generate, in the second dimension, a subset of weights corresponding to the inner corner and another subset of weights corresponding to the outer corner.

24. The medium of claim 17, wherein the instructions configured to cause the one or more processors to update (v) and (vi) are further configured to cause the one or more processors to:
compute, in the first dimension, a third set of contour points as a function of the first set of contour point locations, the first filter function, and the first set of weights; and
compute, in the second dimension, a fourth set of contour points as a function of the second set of contour point locations, the second filter function, and the second set of weights.

25. The medium of claim 24, wherein the instructions configured to cause the one or more processors to compute the third set of contour points are further configured to cause the one or more processors to:
determine at each point of the first set of contour points whether a sum of weights of the first set of weights at that particular point is equal to zero;
responsive to the sum not being zero, transform a particular point of the first set of contour point locations by application of the first filter function and taking a weighted average of the filtered point using the first set of weights; and
responsive to the sum being zero, not transform the particular point of the first set of contour point locations, and
wherein the instructions configured to cause the one or more processors to compute the fourth set of contour points are further configured to cause the one or more processors to:
determine at each point of the second set of contour points whether a sum of weights of the second set of weights at that particular point is equal to zero;
responsive to the sum not being zero, transform the particular point of the second set of contour point locations by application of the second filter function and taking a weighted average of the filtered point using the second set of weights; and
responsive to the sum being zero, not transform the particular point of the second set of contour point locations.

26. The medium of claim 16, wherein the instructions configured to cause the one or more processors to generate the rounded contour are further configured to cause the one or more processors to:
combine the converted first and second sets of contour point locations to generate a set of 2D contour points; and
join the set of 2D contour points to generate the rounded contour.

27. The medium of claim 26, wherein the instructions configured to cause the one or more processors to join the contour points are further configured to cause the one or more processors to join adjacent points of the set of 2D contour points by a linear function, a polynomial function or a combination of linear and polynomial functions, to generate an enclosed contour.

28. The medium of claim 16, wherein the instructions are further configured to cause the one or more processors to generate a mask design based on the rounded contour, wherein the generation of the mask design comprises simulation of a patterning process using the rounded contour.

29. The medium of claim 16, wherein the instructions are further configured to cause the one or more processors to:
access a design layout comprising a plurality of contour representation;
generate rounded contours for each of the plurality of the contour representations by converting each contour representation into ID representations, applying filters to each of the ID representations, and combining the filtered ID contour representations;
simulate, using the rounded contours, an optimal proximity correction process to generate mask patterns;
determine whether the mask patterns satisfy mask rule check (MRC) conditions; and
responsive to the mask patterns not satisfying the MRC, adjusting the design layout.

30. The medium of claim 16, wherein each of the first filter function and the second filter function comprises a Gaussian filter and/or a low pass filter.

31. A non-transitory computer-readable medium comprising instructions stored therein, the instructions, when executed by one or more processors, are configured to cause the one or more processors to at least:
convert a contour representation of a mask pattern to a one dimensional (1D) representation using a unit directional vector and constrain the 1D representation to satisfy a constraint that is proportional to the unit directional vector;
determine (i) a first function of the 1D representation by taking of a gradient of the 1D representation with respect to a first dimension, and (ii) a second function of the 1D representation by taking of a gradient of the 1D representation with respect to a second dimension, the first and the second functions satisfying the constraint;
generate (i) a first filtered function by convolution of the first function with a first filter, and (ii) a second filtered function by convolution of the second function with a second filter; and
generate a rounded contour for a mask pattern by combination of the first filtered function and the second filtered function of the contour representation.

32. The medium of claim 31, wherein the instructions are further configured to cause the one or more processors to:
distinguish a first type of corners in the contour representation and a second type of corners in the contour representation; and
define the first filter function and/or the second filter function to comprise a filter function for the first type of corners and another filter function for the second type of corners.

33. The medium of claim 31, wherein the instructions configured to cause the one or more processors to convert the contour representation are further configured to cause the one or more processors to:
select a starting point on the contour representation; and
transform an enclosed shape of the contour representation into a straight line by unfolding the contour representation from the starting point.

34. The medium of claim 31, wherein the instructions configured to cause the one or more processors to determine the first function of the 1D representation are further configured to cause the one or more processors to generate a step function in the first dimension based on a length of segments of the contour representation in the first dimension and the second dimension, and a direction of traverse along the contour representation.

35. The medium of claim 31, wherein the instructions configured to cause the one or more processors to determine the second function of the 1D representation are further configured to cause the one or more processors to generate a step function in the second dimension based on a length of segments of the contour representation in the first dimension and the second dimension, and a direction of traverse along the contour representation.
